(19) United States
(12) Patent Application Publication
(10) Pub. No.: US 2025/0348000 A1
(43) Pub. Date: Nov. 13, 2025

(54) RESIST UNDERLAYER FILM-FORMING COMPOSITION

(71) Applicant: NISSAN CHEMICAL CORPORATION, Tokyo (JP)

(72) Inventors: Shou SHIMIZU, Toyama-shi (JP); Kosuke IGATA, Toyama-shi (JP); Mamoru TAMURA, Toyama-shi (JP)

(73) Assignee: NISSAN CHEMICAL CORPORATION, Tokyo (JP)

(21) Appl. No.: 18/870,564

(22) PCT Filed: Jun. 6, 2023
(86) PCT No.: PCT/JP2023/020930

§ 371 Date: Nov. 29, 2024

(30) Foreign Application Priority Data
Jun. 15, 2022 (JP) 2022-096391

(51) Int. Cl. G03F 7/039; C09D 163/00; G03F 7/00; G03F 7/004; G03F 7/095; G03F 7/36; H01L 21/311

(52) U.S. Cl. CPC G03F 7/0392; C09D 163/00; G03F 7/0045; G03F 7/095; G03F 7/36; H01L 21/31144; G03F 7/70033

(57) ABSTRACT

A resist underlayer film-forming composition for EB or EUV lithography, the resist underlayer film-forming composition including: a hydroxy group-containing polymer; a photoacid generator containing a hydroxy group in a cationic part; a crosslinking agent that can react with a hydroxy group; and a solvent.

### TECHNICAL FIELD

The present invention relates to a resist underlayer film-forming composition, a resist underlayer film, a semiconductor processing substrate, a semiconductor element producing method, and a pattern forming method.

### BACKGROUND ART

In the related art, fine processing by lithography using a resist composition has been performed in the production of semiconductor devices. The fine processing is a processing method in which a thin film of a photoresist composition is formed on a semiconductor substrate such as a silicon wafer, irradiated with active rays such as ultraviolet rays through a mask pattern with a device pattern drawn thereon, and developed, and the substrate is etched using the obtained photoresist pattern as a protective film to form fine irregularities corresponding to the photoresist pattern on a surface of the substrate. In recent years, the degree of integration of semiconductor devices has been increased, and as active rays to be used, EUV light (wavelength: 13.5 nm) or electron beams (EB) has been studied to be put into practical use for the most advanced fine processing, in addition to i-rays (wavelength: 365 nm), a KrF excimer laser (wavelength: 248 nm), and an ArF excimer laser (wavelength: 193 nm) which have been used in the related art. At the same time, defects in the formation of the resist pattern due to an influence from the semiconductor substrate and the like are a big problem. Therefore, in order to solve this problem, a method of providing a resist underlayer film between a resist and a semiconductor substrate has been widely studied.

Patent Literature 1 discloses an underlayer film-forming composition for lithography containing a naphthalene ring having a halogen atom. Patent Literature 2 discloses a halogenated antireflective film. Patent Literature 3 discloses a resist underlayer film-forming composition. Patent Literature 4 discloses an antireflective coating composition for improving a pattern collapse margin in negative tone development, which contains a polymer, a photoacid generator including a crosslinkable group, a compound capable of crosslinking the polymer and the photoacid generator, a thermal acid generator, and an organic solvent.

### CITATION LIST

### Patent Literatures

Patent Literature 1: WO 2006/003850 A
Patent Literature 2: JP 2005-526270 A
Patent Literature 3: WO 2020/111068 A
Patent Literature 4: JP 2021-18429 A

### SUMMARY OF INVENTION

### Technical Problem

Examples of the characteristics required for a resist underlayer film include no occurrence of intermixing with a resist film formed on an upper layer (insolubility in a resist solvent).

Examples of the characteristics required for a resist underlayer film further include increasing the sensitivity of the resist film.

The present invention has been made in view of the above circumstances, and an object of the present invention is to provide a resist underlayer film-forming composition capable of forming a resist underlayer film that is excellent in solvent resistance to a resist solvent and can increase the sensitivity of a resist film, a resist underlayer film, a semiconductor processing substrate, a semiconductor element producing method, and a pattern forming method.

### Solution to Problem

The inventors have conducted intensive studies to solve the above-described problems. As a result, they have found that the above-described problems can be solved and have completed the present invention having the following gist.

That is, the present invention includes the following aspects.

[1] A resist underlayer film-forming composition for EB or EUV lithography, the resist underlayer film-forming composition including: a hydroxy group-containing polymer (A); a photoacid generator (B) containing a hydroxy group in a cationic part; a crosslinking agent (C) that can react with a hydroxy group; and a solvent (D).

[2] The resist underlayer film-forming composition for EB or EUV lithography according to [1], in which the polymer (A) is at least one of
(i) a polyaddition product of a polyfunctional epoxy compound and one or more kinds selected from the group consisting of a polyfunctional carboxylic acid, a polyfunctional phenol, a polyfunctional thiol, isocyanuric acids, and barbituric acids,
(ii) a hydroxy group-containing poly(meth)acrylate, and
(iii) an addition-condensation product of an aromatic compound containing a phenolic hydroxy group, an aromatic amine, or an electron-rich aromatic compound, and an aldehyde compound or a carbonyl compound.

[3] The resist underlayer film-forming composition for EB or EUV lithography according to [1] or [2], in which the photoacid generator (B) is a photoacid generator represented by the following Formula (1).

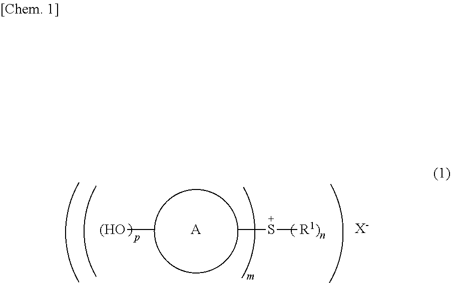

[In Formula (1), p represents an integer of 1≤p≤4.
m represents an integer of 1≤m≤3, n represents an integer of 0≤n≤2, and n+m=3.

A represents a benzene ring which may be substituted or a naphthalene ring which may be substituted.

R¹ represents an alkyl group having 1 to 30 carbon atoms, a phenyl group which may be substituted, or a naphthyl group which may be substituted.

X⁻ represents a monovalent anion.

When m is 2 or more, A—(OH) p's may be the same or different.

When n is 2, R¹'s may be the same or different.]

[4] The resist underlayer film-forming composition for EB or EUV lithography according to any one of [1] to [3], in which the photoacid generator (B) is a photoacid generator represented by the following Formula (1-1).

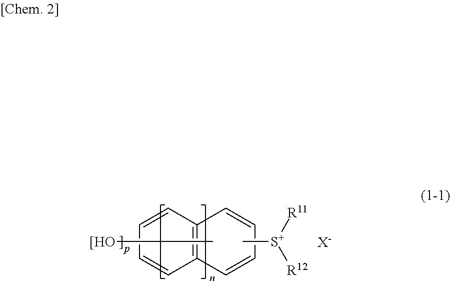

(In Formula (1-1), R¹¹ represents an alkyl group having 1 to 6 carbon atoms. R¹² represents an alkyl group having 1 to 6 carbon atoms. n represents 0 or 1. p represents 1 or 2. X″ represents a monovalent anion.)

[5] The resist underlayer film-forming composition for EB or EUV lithography according to any one of [1] to [4], in which the crosslinking agent (C) is at least one of a melamine compound, a guanamine compound, a glycoluril compound, a urea compound, and a compound having a phenolic hydroxy group.

[6] The resist underlayer film-forming composition for EB or EUV lithography according to any one of [1] to [5], further including: a catalyst (E) for reaction of the crosslinking agent (C) with a hydroxy group.

[7] A resist underlayer film-forming composition including: a hydroxy group-containing polymer (A); a photoacid generator (B) containing a hydroxy group in a cationic part; a crosslinking agent (C) that can react with a hydroxy group; and a solvent (D), in which the photoacid generator (B) is a photoacid generator represented by the following Formula (1-1).

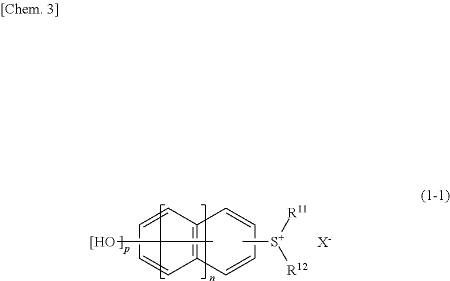

(In Formula (1-1), R¹¹ represents an alkyl group having 1 to 6 carbon atoms. R¹² represents an alkyl group having 1 to 6 carbon atoms. n represents 0 or 1. p represents 1 or 2. X⁻ represents a monovalent anion.)

[8] The resist underlayer film-forming composition according to any one of [1] to [7], which is a resist underlayer film-forming composition for forming a resist underlayer film for a positive photoresist.

[9] A resist underlayer film that is a cured product of the resist underlayer film-forming composition according to any one of [1] to [7].

A semiconductor processing substrate including:
a semiconductor substrate; and
the resist underlayer film according to [9].

A semiconductor element producing method including the steps of:
forming a resist underlayer film on a semiconductor substrate using the resist underlayer film-forming composition according to any one of [1] to [7]; and
forming a resist film on the resist underlayer film.

A pattern forming method including the steps of:
forming a resist underlayer film on a semiconductor substrate using the resist underlayer film-forming composition according to any one of [1] to [7];
forming a resist film on the resist underlayer film;
irradiating the resist film with light or electron beams, and then developing the resist film to obtain a resist pattern; and
etching the resist underlayer film using the resist pattern as a mask.

### Advantageous Effects of Invention

According to the present invention, it is possible to provide a resist underlayer film-forming composition capable of forming a resist underlayer film that is excellent in solvent resistance to a resist solvent and can increase the sensitivity of a resist film, a resist underlayer film for EB or EUV lithography, a semiconductor processing substrate, a semiconductor element producing method, and a pattern forming method.

### DESCRIPTION OF EMBODIMENTS

Hereinafter, the present invention will be described in detail. Note that the following description of constituent requirements to be described below is an example for describing the present invention, and the present invention is not limited to the content thereof.

### (Resist Underlayer Film-Forming Composition)

A resist underlayer film-forming composition of the present invention contains a hydroxy group-containing polymer (A), a photoacid generator (B) containing a hydroxy group in a cationic part, a crosslinking agent (C) that can react with a hydroxy group, and a solvent (D).

In a case where the resist underlayer film-forming composition of the present invention contains the hydroxy group-containing polymer (A), the photoacid generator (B) containing a hydroxy group in a cationic part, and the crosslinking agent (C) that can react with a hydroxy group, the photoacid generator (B) is incorporated into a crosslinking structure of a resist underlayer film. Therefore, even when the resist underlayer film comes into contact with a resist solvent, the photoacid generator (B) is less likely to be eluted from the resist underlayer film. As a result, the resist underlayer film obtained from the resist underlayer film-forming composition of the present invention is excellent in solvent resistance to a resist solvent.

Furthermore, since the photoacid generator (B) is incorporated into the crosslinking structure of the resist underlayer film and the solvent resistance to the resist solvent is improved, the solvent resistance to the resist solvent is less likely to decrease even if the content of the photoacid generator (B) is increased. Therefore, the content of the photoacid generator (B) can be increased. As a result, the sensitivity of a resist film can be increased.

The resist underlayer film-forming composition of the present invention can be suitably used as a resist underlayer film-forming composition for EB or EUV lithography. In the EB or EUV lithography, the resist underlayer film does not need to have an antireflection function. Therefore, the resist underlayer film-forming composition for EB or EUV lithography differs from a composition for antireflection (for example, an antireflective coating composition) in terms of purpose and use.

In addition, the resist underlayer film-forming composition of the present invention is preferably a resist underlayer film-forming composition for forming a resist underlayer film for a positive photoresist.

### <Hydroxy Group-Containing Polymer (A)>

The hydroxy group-containing polymer (A) (hereinafter, may be referred to as the polymer (A)) is not particularly limited as long as it has a hydroxy group. Examples of the hydroxy group include primary hydroxy group, secondary hydroxy group, tertiary hydroxy group, and phenolic hydroxy group.

The polymer (A) has, for example, a hydroxy group bonded to a secondary or tertiary carbon atom.

The polymer (A) has, for example, three or more hydroxy groups in the molecule.

The polymer (A) is preferably at least one of the following (i) to (iii).
(i) A polyaddition product (polymer (A-i)) of a polyfunctional epoxy compound and one or more kinds selected from the group consisting of a polyfunctional carboxylic acid, a polyfunctional phenol, a polyfunctional thiol, isocyanuric acids, and barbituric acids
(ii) A hydroxy group-containing poly(meth)acrylate (polymer (A-ii))
(iii) An addition-condensation product (polymer (A-iii)) of an aromatic compound containing a phenolic hydroxy group, an aromatic amine, or an electron-rich aromatic compound, and an aldehyde compound or a carbonyl compound

### <<(i) Polymer (A-i)>>

The polymer (A-i) is a polyaddition product of a polyfunctional epoxy compound and one or more kinds selected from the group consisting of a polyfunctional carboxylic acid, a polyfunctional phenol, a polyfunctional thiol, isocyanuric acids, and barbituric acids.

As constituent components of the polymer (A-1), components other than a polyfunctional epoxy compound, a polyfunctional carboxylic acid, a polyfunctional phenol, a polyfunctional thiol, isocyanuric acids, and barbituric acids may be contained.

### <<<Polyfunctional Epoxy Compound>>>

The polyfunctional epoxy compound is not particularly limited as long as it is a compound having two or more epoxy groups.

The number of epoxy groups in the polyfunctional epoxy compound is preferably 2 or 3, and more preferably 2.

The polyfunctional epoxy compound does not have, for example, a carboxy group, a phenolic hydroxy group, a mercapto group, and an amino group (—NH—).

As the polyfunctional epoxy compound, a compound represented by the following Formula (11) and a compound represented by the following Formula (12) are preferable.

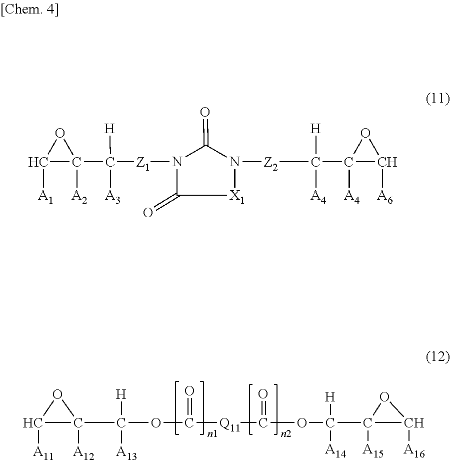

(In Formula (11), X₁ represents a group represented by any one of the following Formulas (11-1) to (11-4). Z₁ and Z₂ each independently represent a single bond or a divalent group represented by the following Formula (11-5). A₁, A₂, A₃, A₄, A₅ and A₆ each independently represent a hydrogen atom, a methyl group, or an ethyl group.

In Formula (12), Q₁ represents a divalent organic group represented by any one of the following Formulas (12-1-1) to (12-1-4). n1 and n2 each independently represent 0 or 1. A₁₁, A₁₂, A₁₃, A₁₄, A₁₅, and A₁₆ each independently represent a hydrogen atom, a methyl group, or an ethyl group.)

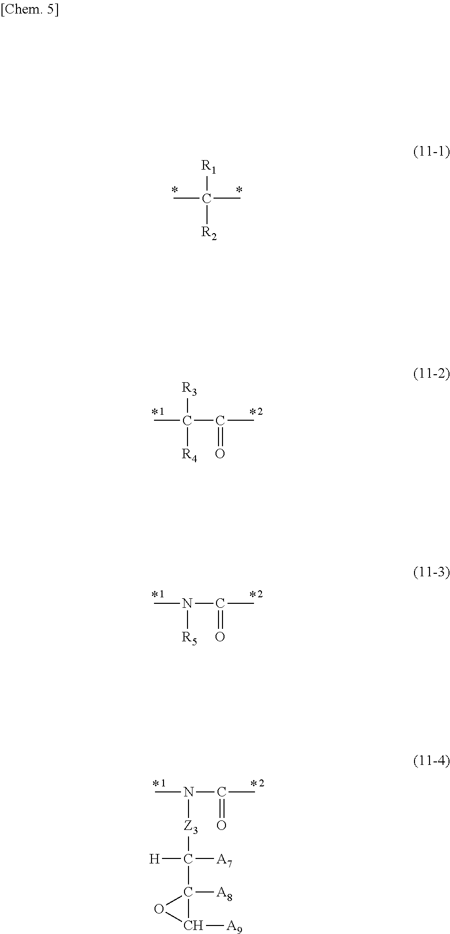

(In Formulas (11-1) to (11-3), R₁ to R₅ each independently represent a hydrogen atom, an alkyl group having 1 to 10 carbon atoms which may be interrupted with an oxygen atom or a sulfur atom, an alkenyl group having 2 to 10 carbon atoms which may be interrupted with an oxygen atom or a sulfur atom, an alkynyl group having 2 to 10 carbon atoms which may be interrupted with an oxygen atom or a sulfur atom, a benzyl group, or a phenyl group, and the phenyl group may be substituted with at least one monovalent group selected from the group consisting of an alkyl group having 1 to 6 carbon atoms, a halogen atom, an alkoxy group having 1 to 6 carbon atoms, a nitro group, a cyano group, and an alkylthio group having 1 to 6 carbon atoms. R₁ and R₂ may be bonded to each other to form a ring having 3 to 6 carbon atoms. R₃ and R₄ may be bonded to each other to form a ring having 3 to 6 carbon atoms.

In Formula (11-4), Z₃ represents a single bond or a divalent group represented by the following Formula (11-5). A₇, A₈, and A₉ each independently represent a hydrogen atom, a methyl group, or an ethyl group.

* represents a bond.

*1 represents a bond bonded to a carbon atom in Formula (11). * 2 represents a bond bonded to a nitrogen atom in Formula (11).)

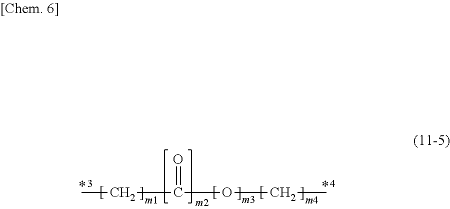

(In Formula (11-5), m1 is an integer of 0 to 4, m2 is 0 or 1, m3 is 0 or 1, and m4 is an integer of 0 to 2. In a case where m3 is 1, m1 and m2 cannot both be 0 at the same time. * 3 represents a bond bonded to a nitrogen atom in Formula (11) or (11-4). * 4 represents a bond.)

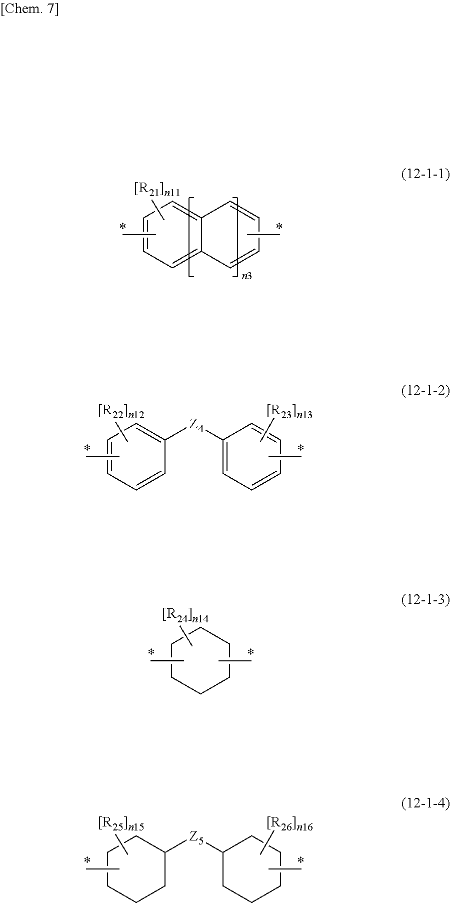

(In Formulas (12-1-1) to (12-1-4), R₂₁ to R₂₆ each independently represent a halogen atom, a hydroxy group, an alkyl group having 1 to 6 carbon atoms, an alkenyl group having 2 to 6 carbon atoms, an alkynyl group having 2 to 6 carbon atoms, an alkoxy group having 1 to 6 carbon atoms, an alkenyloxy group having 2 to 6 carbon atoms, an alkynyloxy group having 2 to 6 carbon atoms, an acyl group having 2 to 6 carbon atoms, an aryloxy group having 6 to 12 carbon atoms, an arylcarbonyl group having 7 to 13 carbon atoms, or an aralkyl group having 7 to 13 carbon atoms. * represents a bond.

In Formula (12-1-1), n3 represents 0 or 1. When n3 is 0, n11 represents an integer of 0 to 4. When n3 is 1, n11 represents an integer of 0 to 6. When two or more R₂₁'s are present, the two or more R₂₁'s may be the same or different.

In Formula (12-1-2), Z₄ represents a single bond, an oxygen atom, a sulfur atom, a carbonyl group, a sulfonyl group, or an alkylene group having 1 to 6 carbon atoms. n12 and n13 each independently represent an integer of 0 to 4. When two or more R₂₂'s are present, the two or more R₂₂'S may be the same or different. When two or more R₂₃'S are present, the two or more R₂₃'s may be the same or different.

In Formula (12-1-3), n14 represents an integer of 0 to 4. When two or more R₂₄'s are present, the two or more R₂₄'s may be the same or different.

In Formula (12-1-4), Z₅ represents a single bond, an oxygen atom, a sulfur atom, a carbonyl group, a sulfonyl group, or an alkylene group having 1 to 6 carbon atoms. n15 and n16 each independently represent an integer of 0 to 4. When two or more R₂₅'s are present, the two or more R₂₅'S may be the same or different. When two or more R₂₆'s are present, the two or more R₂₆'s may be the same or different.)

In the present specification, examples of the halogen atom include fluorine atom, chlorine atom, bromine atom, and iodine atom.

In the present specification, the alkyl group is not limited to a linear one, and may be branched or cyclic. Examples of the linear or branched alkyl group include methyl group, ethyl group, isopropyl group, tert-butyl group, and n-hexyl group. Examples of the cyclic alkyl group (cycloalkyl group) include cyclobutyl group, cyclopentyl group, and cyclohexyl group.

In the present specification, examples of the alkoxy group include methoxy group, ethoxy group, n-pentyloxy group, and isopropoxy group.

In the present specification, examples of the alkylthio group include methylthio group, ethylthio group, n-pentylthio group, and isopropylthio group.

In the present specification, examples of the alkenyl group include ethenyl group, 1-propenyl group, 2-propenyl group, 1-methyl-1-ethenyl group, 1-butenyl group, 2-butenyl group, 3-butenyl group, 2-methyl-1-propenyl group, and 2-methyl-2-propenyl group.

In the present specification, examples of the alkynyl group include a group in which a double bond of an alkenyl group listed in “alkenyl group” described above is substituted with a triple bond.

In the present specification, examples of the alkenyloxy group include vinyloxy group, 1-propenyloxy group, 2-n-propenyloxy group (allyloxy group), 1-n-butenyloxy group, and prenyloxy group.

In the present specification, examples of the alkynyloxy group include 2-propynyloxy group, 1-methyl-2-propynyloxy group, 2-methyl-2-propynyloxy group, 2-butynyloxy group, and 3-butynyloxy group.

In the present specification, examples of the acyl group include acetyl group and propionyl group.

In the present specification, examples of the aryloxy group include phenoxy group and naphthyloxy.

In the present specification, examples of the arylcarbonyl group include phenylcarbonyl group.

In the present specification, examples of the aralkyl group include benzyl group and phenethyl group.

In the present specification, examples of the alkylene group include methylene group, ethylene group, 1,3-propylene group, 2,2-propylene group, 1-methylethylene group, 1,4-butylene group, 1-ethylethylene group, 1-methylpropylene group, 2-methylpropylene group, 1,5-pentylene group, 1-methylbutylene group, 2-methylbutylene group, 1,1-dimethylpropylene group, 1,2-dimethylpropylene group, 1-ethylpropylene group, 2-ethylpropylene group, 1,6-hexylene group, 1,4-cyclohexylene group, 1,8-octylene group, 2-ethyloctylene group, 1,9-nonylene group, and 1,10-decylene group.

Examples of the compound represented by Formula (11) include the following compounds.

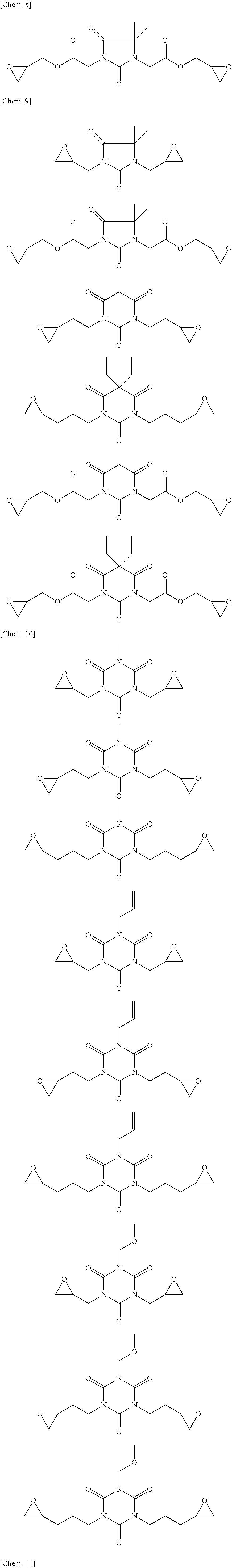

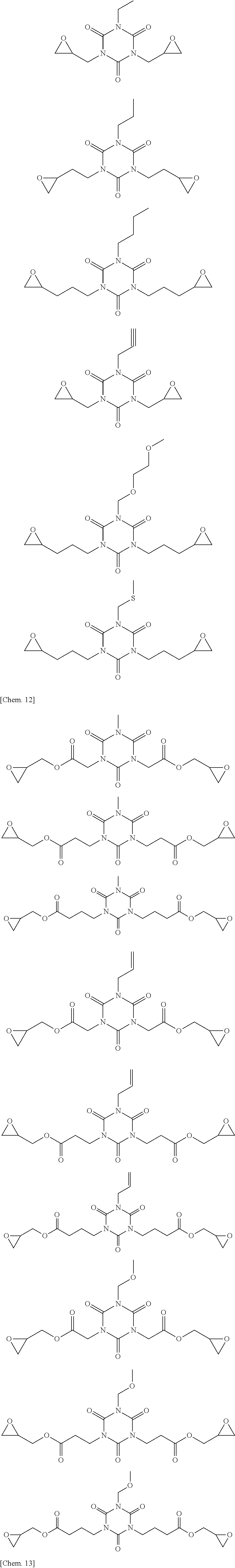

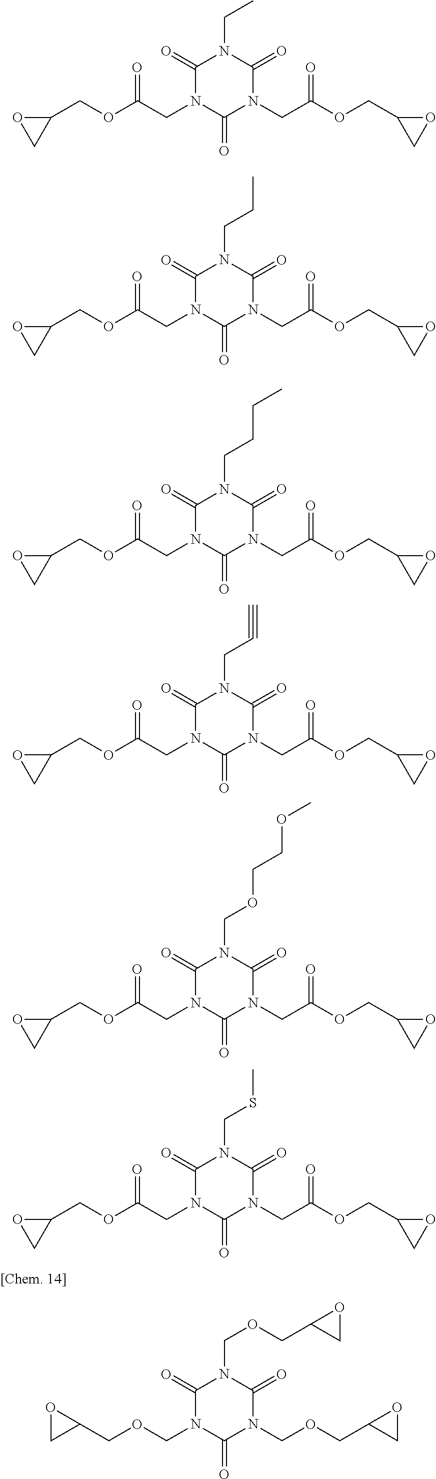

Examples of the compound represented by Formula (12) include the following compounds.

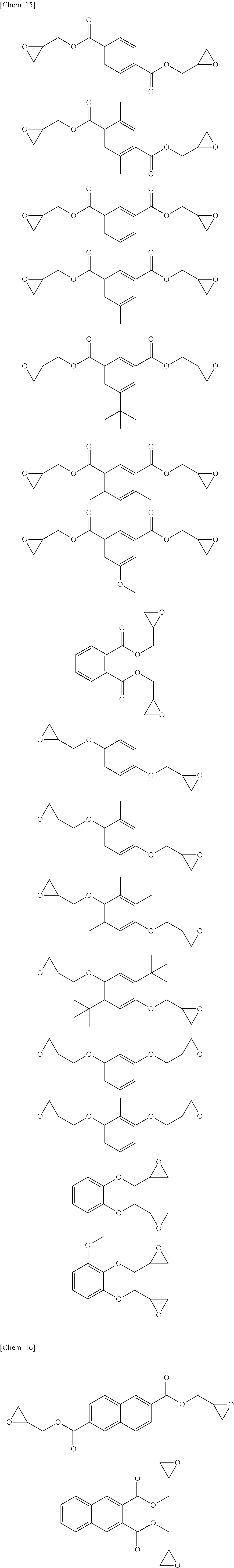

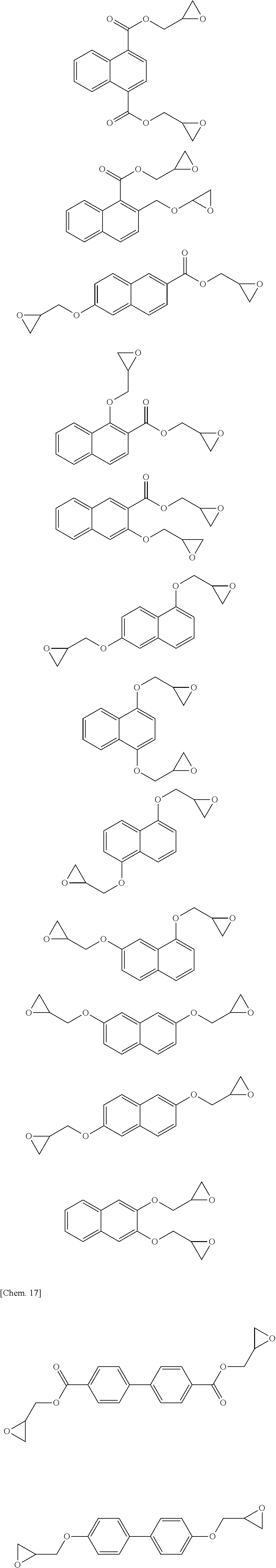

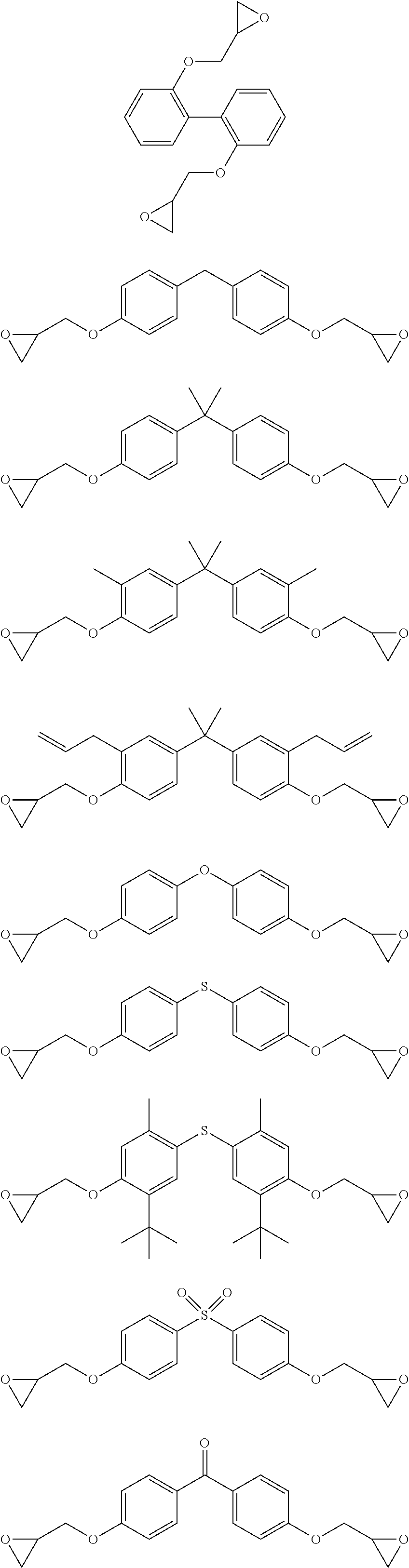

Examples of other polyfunctional epoxy compounds include, but are not limited thereto, 1,2,7,8-diepoxyoctane, 1,4-butanediol diglycidyl ether, 1,6-hexanediol diglycidyl ether, 1,6-dimethylolperfluorohexane diglycidyl ether, (poly)ethylene glycol diglycidyl ether, (poly) propylene glycol diglycidyl ether, neopentyl glycol diglycidyl ether, glycerol triglycidyl ether, diglycerol polyglycidyl ether, trimethylolethane triglycidyl ether, trimethylolpropane triglycidyl ether, pentaerythritol diglycidyl ether, pentaerythritol tetraglycidyl ether, pentaerythritol polyglycidyl ether, sorbitol polyglycidyl ether, 1,4-cyclohexanedimethanol diglycidyl ether, dicyclopentadiene dimethanol diglycidyl ether, 2,6-diglycidylphenyl=glycidyl=ether, 1,1,2,2-tetrakis(4-glycidyloxyphenyl) ethane, 1,1,3-tris(4-glycidyloxyphenyl) propane, bisphenol hexafluoroacetone diglycidyl ether, bis(2,3-epoxycyclopentyl) ether, 1,2-bis(3,4-epoxycyclohexylmethoxy) ethane, ethylene glycol bis(3,4-epoxycyclohexanecarboxylate), 3,4-epoxycyclohexanecarboxylic acid (3,4-epoxycyclohexyl)methyl, 4,5-epoxy-2-methylcyclohexanecarboxylic acid 4,5-epoxy-2-methylcyclohexylmethyl, bis(3,4-epoxycyclohexylmethyl) adipate, 1,2-epoxy-4-(epoxyethyl)cyclohexane, 4-(spiro[3,4-epoxycyclohexane-1,5′-[1,3]dioxane]-2′-yl)-1,2-epoxycyclohexane, diglycidyl adipate, diglycidyl phthalate, diglycidyl tetrahydrophthalate, diglycidyl 1,2-cyclohexanedicarboxylate, N, N-diglycidyl-4-glycidyloxyaniline, N, N,N′,N′-tetraglycidyl-m-xylylenediamine, 1,3-bis(N, N-diglycidylaminomethyl) cyclohexane, 4,4′-methylenebis(N, N-diglycidylaniline), 2-(4,4-dimethylpentane-2-yl)-5,7,7-trimethyloctanoic acid 2,2-bis(glycidyloxymethyl)butyl, bisphenol A type epoxy resin, bisphenol F type epoxy resin, hydrogenated bisphenol A type epoxy resin, hydrogenated bisphenol F type epoxy resin, bisphenol S type epoxy resin, alicyclic epoxy resin, trisphenolmethane type epoxy resin, tetraphenolethane type epoxy resin, alicyclic polyglycidyl ether type epoxy resin, phenol novolak type epoxy resin, cresol novolak type epoxy resin, naphthalene novolak type epoxy resin, anthracene novolak type epoxy resin, biphenylene novolak type epoxy resin, xylylene novolak type epoxy resin, triphenol methane novolak type epoxy resin, tetrakisphenol novolak type epoxy resin, and dicyclopentadiene novolak type epoxy resin.

The molecular weight of the polyfunctional epoxy compound is not particularly limited, and is 150 to 600, for example.

The polyfunctional epoxy compounds can be used alone or in combination of two or more thereof.

### <<<Polyfunctional Carboxylic Acid>>>

The polyfunctional carboxylic acid is not particularly limited as long as it is a compound having two or more carboxy groups.

The number of carboxy groups in the polyfunctional carboxylic acid is preferably 2 or 3, and more preferably 2. The polyfunctional carboxylic acid having two carboxy groups is also referred to as a dicarboxylic acid.

The polyfunctional carboxylic acid does not have, for example, an epoxy group.

As the polyfunctional carboxylic acid, a compound represented by the following Formula (13) is preferable.

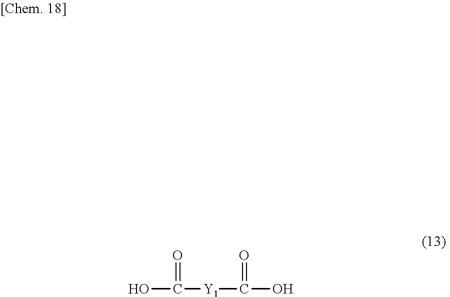

(In Formula (13), Y₁ represents an organic group having 1 to 10 carbon atoms.)

Examples of Y₁ include a hydrocarbon group having 1 to 10 carbon atoms which may be interrupted with at least one of an oxygen atom and a sulfur atom. In this case, Y₁ may have two or more oxygen atoms. In addition, Y₁ may have two or more sulfur atoms, and two sulfur atoms may be consecutive in Y₁.

Examples of the hydrocarbon group include alkylene group. The alkylene group may be linear, branched, or cyclic.

Examples of the compound represented by Formula (13) include the following compounds.

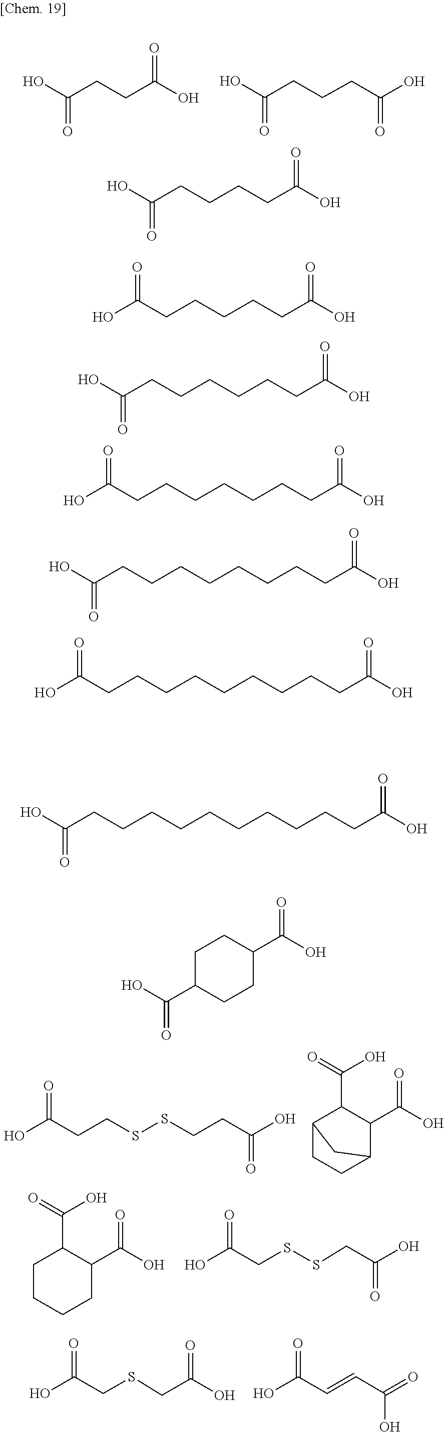

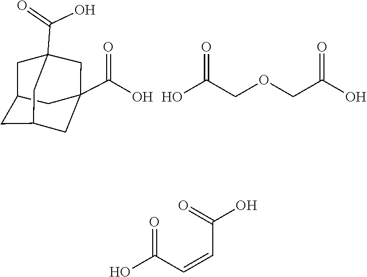

Examples of the dicarboxylic acid include aliphatic dicarboxylic acid, alicyclic dicarboxylic acid, and aromatic group-containing dicarboxylic acid. Specific examples thereof are given below, but the following examples may overlap with the specific examples of Formula (13) described above.

Examples of the aliphatic dicarboxylic acid include malonic acid, dimethylmalonic acid, succinic acid, fumaric acid, glutaric acid, adipic acid, muconic acid, 2-methyladipic acid, trimethyladipic acid, pimelic acid, 2,2-dimethylglutaric acid, 3,3-diethylsuccinic acid, azelaic acid, sebacic acid, and suberic acid.

Examples of the alicyclic dicarboxylic acid include 1,1-cyclopropane dicarboxylic acid, 1,2-cyclopropane dicarboxylic acid, 1,1-cyclobutane dicarboxylic acid, 1,2-cyclobutane dicarboxylic acid, 1,3-cyclobutane dicarboxylic acid, 3,4-diphenyl-1,2-cyclobutane dicarboxylic acid, 2,4-diphenyl-1,3-cyclobutane dicarboxylic acid, 3,4-bis(2-hydroxyphenyl)-1,2-cyclobutane dicarboxylic acid, 2,4-bis(2-hydroxyphenyl)-1,3-cyclobutane dicarboxylic acid, 1-cyclobutene-1,2-dicarboxylic acid, 1-cyclobutene-3,4-dicarboxylic acid, 1,1-cyclopentane dicarboxylic acid, 1,2-cyclopentane dicarboxylic acid, 1,3-cyclopentanedicarboxylic acid, 1,1-cyclohexanedicarboxylic acid, 1,2-cyclohexanedicarboxylic acid, 1,3-cyclohexanedicarboxylic acid, 1,4-cyclohexanedicarboxylic acid, 1,4-(2-norbornene)dicarboxylic acid, norbornene-2,3-dicarboxylic acid, bicyclo[2.2.2]octane-1,4-dicarboxylic acid, bicyclo[2.2.2]octane-2,3-dicarboxylic acid, 2,5-dioxo-1,4-bicyclo[2.2.2]octane dicarboxylic acid, 1,3-adamantane dicarboxylic acid, 4,8-dioxo-1,3-adamantane dicarboxylic acid, 2,6-spiro[3.3]heptane dicarboxylic acid, and 1,3-adamantane diacetic acid.

Examples of the aromatic group-containing dicarboxylic acid include o-phthalic acid, isophthalic acid, terephthalic acid, 5-methylisophthalic acid, 5-tert-butylisophthalic acid, 5-aminoisophthalic acid, 5-hydroxyisophthalic acid, 2,5-dimethylterephthalic acid, tetramethylterephthalic acid, 1,4-naphthalenedicarboxylic acid, 2,5-naphthalenedicarboxylic acid, 2,6-naphthalenedicarboxylic acid, 2,7-naphthalenedicarboxylic acid, 1,4-anthracenedicarboxylic acid, 1,4′-anthraquinonedicarboxylic acid, 2,5-biphenyldicarboxylic acid, 4,4′-biphenyldicarboxylic acid, 1,5-biphenylenedicarboxylic acid, 4,4″-terphenyldicarboxylic acid, 4,4′-diphenylmethane dicarboxylic acid, 4,4′-diphenylethane dicarboxylic acid, 4,4′-diphenylpropane dicarboxylic acid, 4,4′-diphenylhexafluoropropane dicarboxylic acid, 4,4′-diphenyl ether dicarboxylic acid, 4,4′-bibenzyl dicarboxylic acid, 4,4′-stilbenzyl carboxylic acid, 4,4′-trandicarboxylic acid, 4,4′-carbonyl dibenzoic acid, 4,4′-sulfonyl dibenzoic acid, 4,4′-dithiodibenzoic acid, p-phenylene diacetic acid, 3,3′-p-phenylene dipropionic acid, 4-carboxycinnamic acid, p-phenylene diacrylic acid, 3,3′-(4-4′-(methylenedi-p-phenylene)) dipropionic acid, 4,4′-(4,4′-(oxydi-p-phenylene)) dipropionic acid, 4,4′-(4,4′-(oxydi-p-phenylene)) dibutyric acid, (isopropylidenedi-p-phenylenedioxy) dibutyric acid, bis(p-carboxyphenyl)dimethylsilane, 1,5-(9-oxofluorene)dicarboxylic acid, 3,4-furandicarboxylic acid, 4,5-thiazole dicarboxylic acid, 2-phenyl-4,5-thiazole dicarboxylic acid, 1,2,5-thiadiazole-3,4-dicarboxylic acid, 1,2,5-oxadiazole-3,4-dicarboxylic acid, 2,3-pyridinedicarboxylic acid, 2,4-pyridinedicarboxylic acid, 2,5-pyridinedicarboxylic acid, 2,6-pyridinedicarboxylic acid, 3,4-pyridinedicarboxylic acid, 3,5-pyridinedicarboxylic acid, and 6-pyridinedicarboxylic acid.

The molecular weight of the polyfunctional carboxylic acid is not particularly limited, and is 100 to 400, for example.

The polyfunctional carboxylic acids can be used alone or in combination of two or more thereof.

### <<<Polyfunctional Phenol>>

The polyfunctional phenol is not particularly limited as long as it is a compound having two or more phenolic hydroxy groups.

The aromatic hydrocarbon ring to which the phenolic hydroxy group is bonded may be a benzene ring or a naphthalene ring.

The number of phenolic hydroxy groups in the polyfunctional phenol is preferably 2 or 3, and more preferably 2.

The polyfunctional phenol does not have, for example, an epoxy group.

As the polyfunctional phenol, a compound represented by the following Formula (14) is preferable.

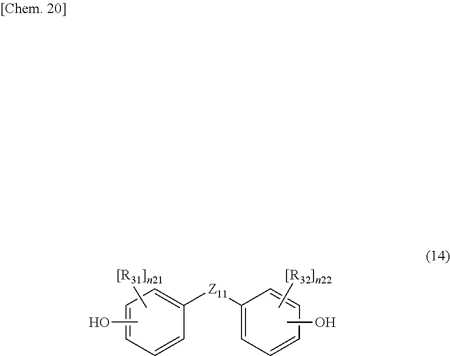

(In Formula (14), R₃₁ and R₃₂ each independently represent a halogen atom, an alkyl group having 1 to 6 carbon atoms, an alkenyl group having 2 to 6 carbon atoms, an alkynyl group having 2 to 6 carbon atoms, an alkoxy group having 1 to 6 carbon atoms, an alkenyloxy group having 2 to 6 carbon atoms, an alkynyloxy group having 2 to 6 carbon atoms, an acyl group having 2 to 6 carbon atoms, an aryloxy group having 6 to 12 carbon atoms, an arylcarbonyl group having 7 to 13 carbon atoms, or an aralkyl group having 7 to 13 carbon atoms.

Z₁₁ represents a single bond, an oxygen atom, a sulfur atom, a carbonyl group, a sulfonyl group, or an alkylene group having 1 to 6 carbon atoms which may be substituted with a halogen atom.

n21 and n22 each independently represent an integer of 0 to 4.

When two or more Rai's are present, the two or more R₃₁'s may be the same or different. When two or more R₃₂'S are present, the two or more R₃₂'s may be the same or different.)

In the substitution of the alkylene group having 1 to 6 carbon atoms with a halogen atom, the substitution may be partial or complete.

Examples of the compound represented by Formula (14) include the following compounds.

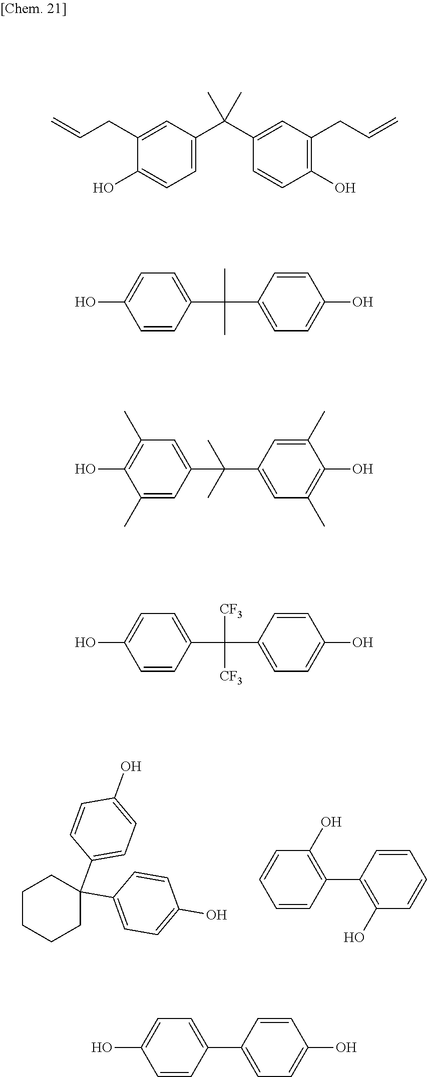

The molecular weight of the polyfunctional phenol is not particularly limited, and is 150 to 400, for example.

The polyfunctional phenols can be used alone or in combination of two or more thereof.

### <<<Polyfunctional Thiol>>>

The polyfunctional thiol is not particularly limited as long as it is a compound having two or more mercapto groups.

The number of mercapto groups in the polyfunctional thiol is preferably 2 or 3, and more preferably 2.

The polyfunctional thiol does not have, for example, an epoxy group.

As the polyfunctional thiol, a compound represented by the following Formula (15) is preferable.

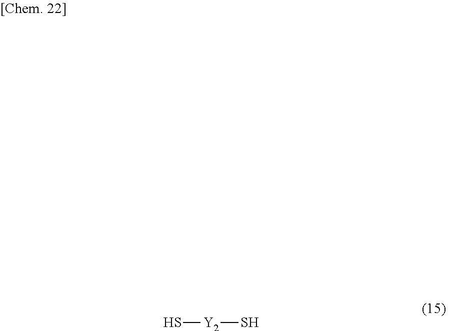

(In Formula (15), Y₂ represents an organic group having 1 to 10 carbon atoms.)

Examples of Y₂ include an alkylene group having 1 to 10 carbon atoms. The alkylene group may be linear, branched, or cyclic.

Examples of the polyfunctional thiol include 1,2-ethanedithiol, 1,3-propanedithiol, bis(2-mercaptoethyl) ether, trimethylolpropane tris(3-mercaptopropionate), tris-[(3-mercaptopropionyloxy)-ethyl]-isocyanurate, tetraethylene glycol bis(3-mercaptopropionate), dipentaerythritol hexakis (3-mercaptopropionate), pentaerythritol tetrakis(3-mercaptobutyrate), 1,4-bis(3-mercaptobutyryloxy) butane, 1,3,5-tris(3-mercaptobutyryloxyethyl)-1,3,5-triazine-2,4,6-(1H, 3H, 5H)-trione, trimethylolpropane tris(3-mercaptobutyrate), trimethylolethane tris(3-mercaptobutyrate), and pentaerythritol tris(3-mercaptopropyl) ether. As the polyfunctional thiol compound, commercially available products such as Karenz MT (registered trademark) PE1, Karenz MT NR1, Karenz MT BD1, TPMB, and TEMB (all manufactured by Showa Denko K.K.), and TMMP, TEMPIC, PEMP, EGMP-4, DPMP, TMMP II-20P, PEMP II-20P, and PEPT (all manufactured by SC Organic Chemical Co., Ltd.) can be adopted.

The molecular weight of the polyfunctional thiol is not particularly limited, and is 80 to 400, for example.

The polyfunctional thiols can be used alone or in combination of two or more thereof.

### <<<Isocyanuric Acids>>>

The isocyanuric acids are not particularly limited as long as they are compounds having an isocyanuric acid skeleton having two or more —NH— groups.

The isocyanuric acids do not have, for example, an epoxy group.

As the isocyanuric acids, a compound represented by the following Formula (16) is preferable.

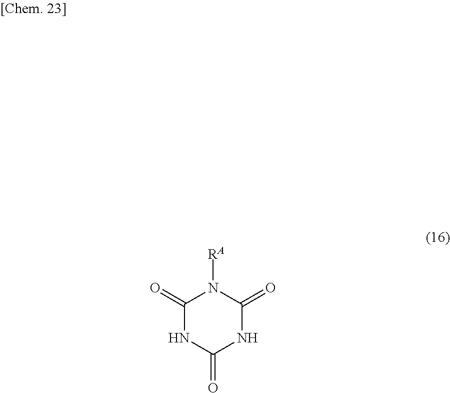

(In Formula (16), R^{A} represents a hydrogen atom or a hydrocarbon group having 1 to 10 carbon atoms.)

Examples of the hydrocarbon group having 1 to 10 carbon atoms represented by R^{A} include an alkyl group having 1 to 10 carbon atoms, an alkenyl group having 2 to 10 carbon atoms, and an alkynyl group having 2 to 10 carbon atoms.

Examples of the isocyanuric acids include the following compounds.

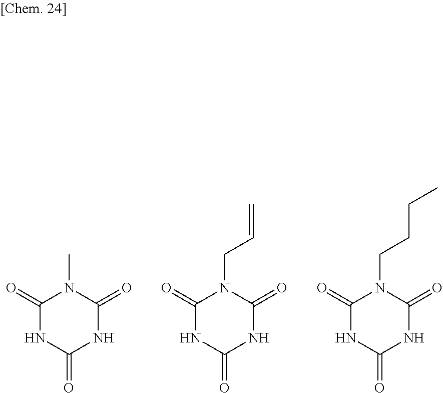

The molecular weight of the isocyanuric acids is not particularly limited, and is 129 to 400, for example.

The isocyanuric acids can be used alone or in combination of two or more thereof.

### <<<Barbituric Acids>>>

The barbituric acids are not particularly limited as long as they are compounds having a barbituric acid skeleton having two —NH— groups.

The barbituric acids do not have, for example, an epoxy group.

As the barbituric acids, a compound represented by the following Formula (17) is preferable.

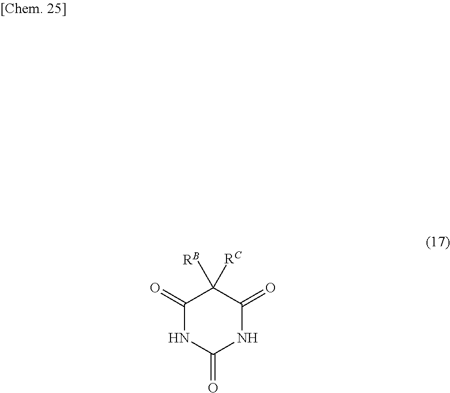

(In Formula (17), RB and RC each independently represent a hydrogen atom or a hydrocarbon group having 1 to 10 carbon atoms.)

Examples of the hydrocarbon group having 1 to 10 carbon atoms represented by RB and RC include an alkyl group having 1 to 10 carbon atoms, an alkenyl group having 2 to 10 carbon atoms, an alkynyl group having 2 to 10 carbon atoms, and an aromatic hydrocarbon group having 6 to 10 carbon atoms.

Examples of the barbituric acids include the following compounds.

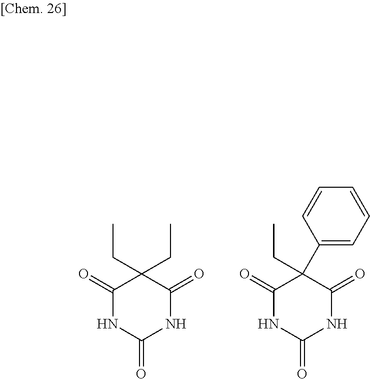

The molecular weight of the barbituric acids is not particularly limited, and is 128 to 400, for example.

The barbituric acids can be used alone or in combination of two or more thereof.

### <<<Other Constituent Components>>

Examples of other constituent components of the polymer (A-i) include monocarboxylic acid.

The monocarboxylic acid is not particularly limited as long as it is a compound having one carboxy group.

The monocarboxylic acid does not have, for example, an epoxy group.

Examples of the monocarboxylic acid include a compound represented by the following Formula (18).

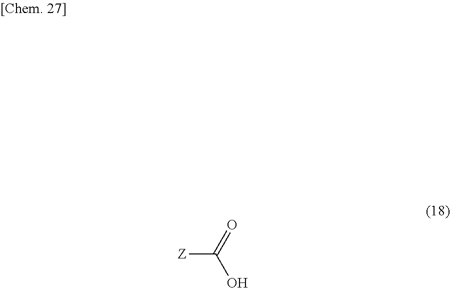

(In Formula (18), Z represents a monovalent organic group in which one hydrogen atom is removed from an aliphatic ring, of the aliphatic ring which may be substituted with a substituent and in which a carbon-carbon bond may be interrupted with a heteroatom.)

Examples of the compound represented by Formula (18) include the following compounds.

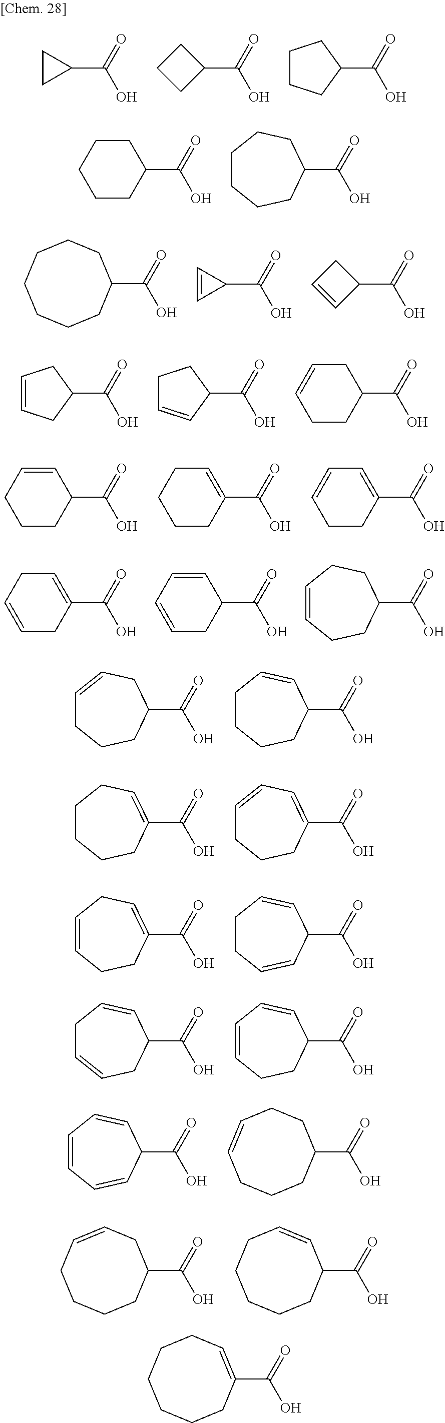

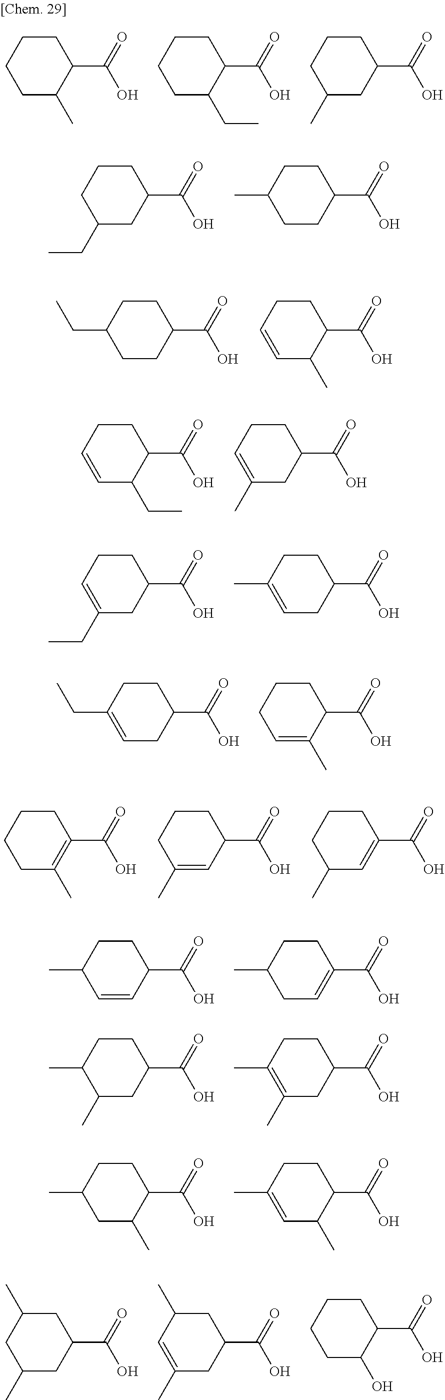

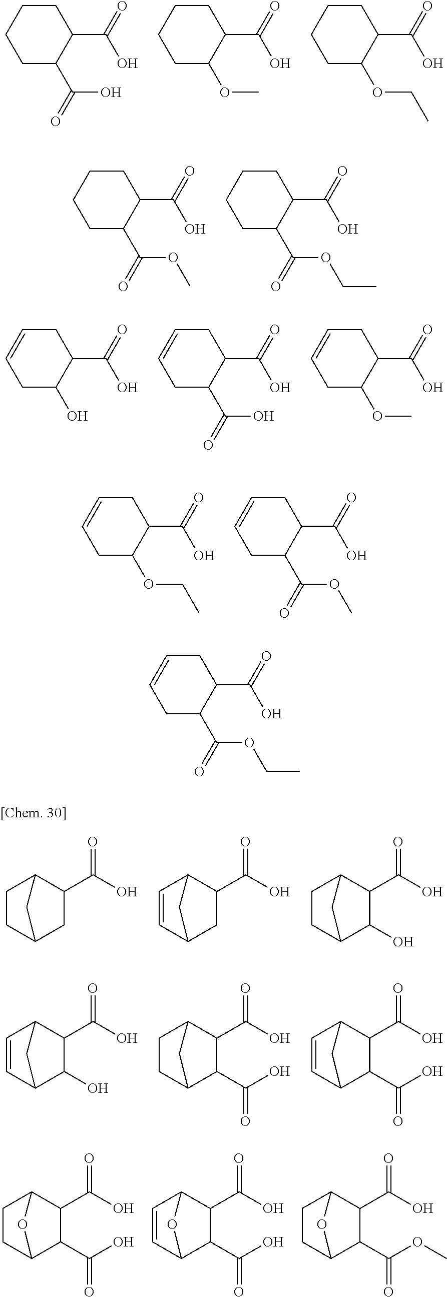

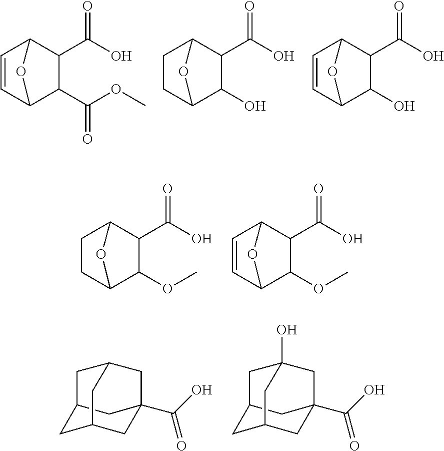

The molecular weight of the monocarboxylic acid is not particularly limited, and is 50 to 400, for example.

The monocarboxylic acids can be used alone or in combination of two or more thereof.

The polyaddition reaction in obtaining the polymer (A-i) may be performed, for example, in the presence of a catalyst. The catalyst is, for example, a quaternary phosphonium salt such as tetrabutylphosphonium bromide or ethyltriphenylphosphonium bromide, or a quaternary ammonium salt such as benzyltriethylammonium chloride. Regarding the amount of the catalyst used, an appropriate amount can be selected and used from a range of 0.1 to 10 mass % relative to the total mass of the polymer raw material used in the reaction. Regarding the temperature and time for the polyaddition reaction, for example, optimum conditions can be selected from a range of 80° C. to 160° C. and a range of 2 to 50 hours.

<<(ii) Polymer (A-ii)>>

The polymer (A-ii) is a hydroxy group-containing poly(meth)acrylate.

The polymer (A-ii) has, for example, a structural unit represented by the following Formula (21).

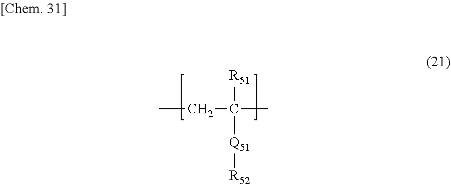

(In Formula (21), R₅₁ represents a hydrogen atom, a methyl group, or a halogen atom, Q₅₁ represents a single bond or a divalent linking group, and R₅₂ represents a monovalent organic group having a hydroxy group.)

The divalent linking group in Q₅₁ is not particularly limited, and examples thereof include —C(═O)O—, —O—, —C(═O)—N(—R)—(R represents a hydrogen atom or an alkyl group having 1 to 4 carbon atoms), —NHC(═O) NH—, —NHC(═O)O—, —C(═O)—, —S—, —SO—, and —NH—.

The monovalent organic group having a hydroxy group in R₅₂ is not particularly limited, and examples thereof include a monovalent organic group having a hydroxy group with 1 to 30 carbon atoms.

Examples of the monovalent organic group having a hydroxy group in R₅₂ include an alkyl group having a hydroxy group with 1 to 10 carbon atoms, an aralkyl group having a hydroxy group, a carbocyclic aromatic group having a hydroxy group, and a heterocyclic aromatic group having a hydroxy group.

The polymer (A-ii) is obtained by, for example, polymerizing a compound having a hydroxy group and a polymerizable unsaturated group.

In addition, the polymer (A-ii) is obtained by, for example, copolymerizing a compound having a hydroxy group and a polymerizable unsaturated group with a compound having a polymerizable unsaturated group as another monomer.

The compound having a hydroxy group and a polymerizable unsaturated group has, for example, one or more ethylenically unsaturated group-containing groups, such as (meth)acryloyl group, vinylphenyl group, propenyl ether group, allyl ether group, and vinyl ether group, and one or more hydroxy groups.

Note that(meth)acryloyl represents acryloyl and/or methacryloyl. Similarly, (meth)acryl represents acryl and/or methacryl, and (meth)acrylate represents acrylate and/or methacrylate.

The ethylenically unsaturated group-containing group is preferably a (meth)acryloyl group, and more preferably an acryloyl group.

In a case where the ethylenically unsaturated group-containing group is a (meth)acryloyl group, examples of the compound having a hydroxy group and a polymerizable unsaturated group include hydroxy group-containing (meth)acrylate.

Examples of the hydroxy group-containing (meth)acrylate include monohydroxy mono(meth)acrylate having one hydroxy group and one (meth)acryloyl group in one molecule, and for example, polyhydroxy mono(meth)acrylate having a plurality of hydroxy groups and one (meth)acryloyl group in one molecule.

Examples of the monohydroxy mono(meth)acrylate include hydroxyalkyl (meth)acrylates such as 2-hydroxyethyl (meth)acrylate, 2-hydroxypropyl(meth)acrylate, 4-hydroxybutyl (meth)acrylate, 2-hydroxybutyl(meth)acrylate, 2-phenoxypropyl(meth)acrylate, and 4-hydroxycyclohexyl (meth)acrylate, and for example, 3-chloro-2-hydroxypropyl (meth)acrylate, 2-hydroxy-3-phenyloxypropyl (meth)acrylate, 2-(meth)acryloyloxyethyl-2-hydroxyethylphthalic acid, 2-hydroxyalkyl (meth)acryloylphosphate, pentanediol mono(meth)acrylate, neopentyl glycol mono(meth)acrylate, polyethylene glycol mono(meth)acrylate, and polypropylene glycol mono(meth)acrylate.

Examples of the polyhydroxy mono(meth)acrylate include trimethylolpropane mono(meth)acrylate, glycerin mono(meth)acrylate, and pentaerythritol mono(meth)acrylate.

In addition, in a case where the ethylenically unsaturated group-containing group is a vinylphenyl group, examples of the compound having a hydroxy group and a polymerizable unsaturated group include 4-vinylphenol, 2-hydroxyethyl-4-vinylphenyl ether, (2-hydroxypropyl)-4-vinylphenyl ether, (2,3-dihydroxypropyl)-4-vinylphenyl ether, and 4-(2-hydroxyethyl) styrene.

In addition, in a case where the ethylenically unsaturated group-containing group is a propenyl ether group, examples of the compound having a hydroxy group and a polymerizable unsaturated group include propenyl alcohol, 2-hydroxyethyl propenyl ether, and 2,3-dihydroxypropyl pronenyl ether.

In addition, in a case where the ethylenically unsaturated group-containing group is an allyl ether group, examples of the compound having a hydroxy group and a polymerizable unsaturated group include allyl alcohol, 2-hydroxyethyl allyl ether, and 2-hydroxypropyl allyl alcohol.

In addition, in a case where the ethylenically unsaturated group-containing group is a vinyl ether group, examples of the compound having a hydroxy group and a polymerizable unsaturated group include 2-hydroxyethyl vinyl ether and 2-hydroxypropyl vinyl ether.

These compounds having a hydroxy group and a polymerizable unsaturated group can be used alone or in combination of two or more thereof.

The compound having a polymerizable unsaturated group to be used for copolymerization with the compound having a hydroxy group and a polymerizable unsaturated group is not particularly limited, and examples thereof include acrylic acid esters, methacrylic acid esters, acrylamides, methacrylamides, allyl compounds, vinyl ethers, vinyl esters, and styrenes.

Examples of the acrylic acid esters include substituted or unsubstituted alkyl acrylate having an alkyl group having 1 to 10 carbon atoms, aralkyl ester of acrylic acid, and aryl ester of acrylic acid.

Examples of the methacrylic acid esters include substituted or unsubstituted alkyl methacrylate having an alkyl group having 1 to 10 carbon atoms, aralkyl ester of methacrylic acid, and aryl ester of methacrylic acid.

Examples of the acrylamides include N-alkylacrylamide, N-arylacrylamide, N, N-dialkylacrylamide, N, N-diarylacrylamide, N-methyl-N-phenylacrylamide, and N-2 acetamidoethyl-N-acetylacrylamide.

Examples of the methacrylamides include N-alkyl methacrylamide, N-aryl methacrylamide, N, N-dialkyl methacrylamide, N, N-diaryl methacrylamide, N-methyl-N-phenyl methacrylamide, and N-ethyl-N-phenyl methacrylamide.

Examples of the vinyl ethers include alkyl vinyl ether and vinyl aryl ether.

Examples of the vinyl esters include vinyl butyrate, vinyl isobutyrate, and vinyl trimethyl acetate.

Examples of the styrenes include styrene, alkylstyrene, alkoxystyrene, halogenated styrene, and carboxystyrene.

<<(iii) Polymer (A-iii)>>

The polymer (A-iii) is an addition-condensation product of an aromatic compound containing a phenolic hydroxy group, an aromatic amine, or an electron-rich aromatic compound, and an aldehyde compound or a carbonyl compound. Addition condensation products of phenol or naphthol, which is an aromatic compound containing a phenolic hydroxy group, and an aldehyde compound or a carbonyl compound are known as phenol novolak and naphthol novolak, respectively, and these can also be used as the polymer (A-iii).

Examples of the aromatic compound containing a phenolic hydroxy group include phenol, dihydroxybenzene, trihydroxybenzene, hydroxynaphthalene, dihydroxynaphthalene, trihydroxynaphthalene, tris(4-hydroxyphenyl) methane, tris(4-hydroxyphenyl) ethane, 1,1,2,2-tetrakis(4-hydroxyphenyl) ethane, 2,2′-biphenol, 1,4-bis[bis(4-hydroxyphenyl)methyl]benzene, and bisphenol fluorene.

Examples of the aromatic amine include aniline, diphenylamine, phenylnaphthylamine, hydroxydiphenylamine, phenylnaphthylamine, N,N′-diphenylethylenediamine, and N,N′-diphenyl-1,4-phenylenediamine, and aromatic amines containing a phenolic hydroxy group on an aromatic ring of these aromatic amines are also included. Aromatic amines containing no phenolic hydroxy group on the aromatic ring are subjected to addition condensation with an aldehyde compound or a carbonyl compound together with an aromatic compound containing a phenolic hydroxy group, and thus a hydroxy group-containing polymer can be synthesized.

Examples of the electron-rich aromatic compound include carbazole and indole, and electron-rich aromatic compounds containing a phenolic hydroxy group on an aromatic ring of these electron-rich aromatic compounds are also included. Electron-rich aromatic compounds containing no phenolic hydroxy group on the aromatic ring are subjected to addition condensation with an aldehyde compound or a carbonyl compound together with an aromatic compound containing a phenolic hydroxy group, and thus a hydroxy group-containing polymer can be synthesized.

The molecular weight of the polymer (A) is not particularly limited.

The weight average molecular weight of the polymer (A) is not particularly limited, and is preferably 2,000 to 100,000, and more preferably 3,000 to 50,000.

The content of the polymer (A) in the resist underlayer film-forming composition is not particularly limited, and is preferably 50 mass % or more, and more preferably 60 mass % or more relative to the film constituent components.

### <Photoacid Generator (B)>

The photoacid generator (B) contains a hydroxy group in the cationic part.

As the hydroxy group, a phenolic hydroxy group is preferable from the viewpoint of reactivity. The phenolic hydroxy group means a hydroxy group directly bonded to an aromatic hydrocarbon ring.

The number of hydroxy groups of the photoacid generator (B) is not particularly limited, and is preferably 1 to 6, more preferably 1 to 4, still more preferably 1 or 2, and particularly preferably 1.

The cationic part is preferably a sulfonium cation.

As the photoacid generator (B), a photoacid generator represented by the following Formula (1) is preferable.

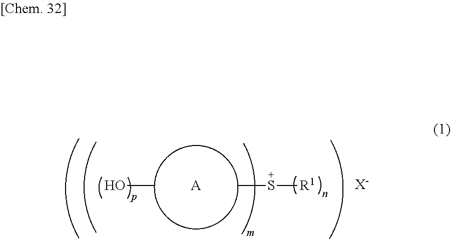

[In Formula (1), p represents an integer of 1≤p≤4.
m represents an integer of 1 $ m $3, n represents an integer of 0≤n≤2, and n+m=3.

A represents a benzene ring which may be substituted or a naphthalene ring which may be substituted.

R¹ represents an alkyl group having 1 to 30 carbon atoms, a phenyl group which may be substituted, or a naphthyl group which may be substituted.

X⁻ represents a monovalent anion.

When m is 2 or more, A—(OH) p's may be the same or different.

When n is 2, R₁'s may be the same or different.]

It is preferable that m=1 and n=2, or m=3 and n=0.

Examples of the substituent in the phenyl group which may be substituted or the naphthyl group which may be substituted, represented by R₁, include halogen atom, alkyl group having 1 to 6 carbon atoms, and alkoxy group having 1 to 6 carbon atoms.

As R¹, an alkyl group having 1 to 30 carbon atoms is preferable, and an alkyl group having 1 to 6 carbon atoms is more preferable.

As the photoacid generator (B), a photoacid generator represented by the following Formula (1-1) is more preferable.

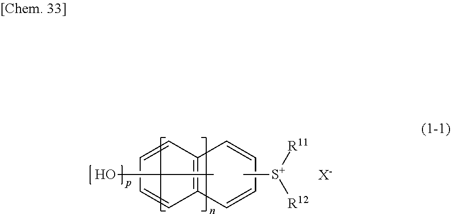

(In Formula (1-1), R¹¹ represents an alkyl group having 1 to 6 carbon atoms. R¹² represents an alkyl group having 1 to 6 carbon atoms. n represents 0 or 1. p represents 1 or 2. X⁻ represents a monovalent anion.)

The monovalent anion in Formulas (1) and (1-1) is not particularly limited, and examples thereof include sulfonate anion, borate anion, and antimonate anion. Among them, a sulfonate anion is preferable. Examples of the sulfonate anion include non-fluorinated sulfonate anion, partially fluorinated sulfonate anion, and fully fluorinated sulfonate anion.

Examples of the sulfonate anion include an anion represented by the following Formula (X₁).

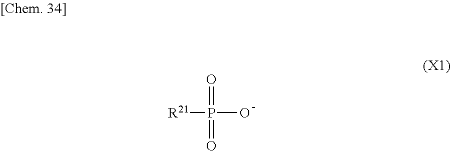

(In Formula (X₁), R²¹ represents an alkyl group having 1 to 4 carbon atoms which may be partially or fully fluorinated.)

As R²¹, a methyl group or a trifluoromethyl group is preferable.

The content of the photoacid generator (B) in the resist underlayer film-forming composition is not particularly limited, and is, for example, 1 mass % to 40 mass %, and preferably 5 mass % to 25 mass % relative to the polymer (A).

### <Crosslinking Agent (C)>

The crosslinking agent (C) is not particularly limited as long as it can react with a hydroxy group.

Examples of the crosslinking agent include a compound having two or more structures shown below.

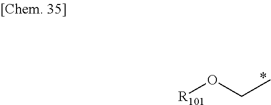

(In the structure, R₁₀₁ represents a hydrogen atom, an alkyl group having 1 to 4 carbon atoms, or an alkoxyalkyl group having 2 to 6 carbon atoms. * represents a bond.)

The bond is bonded to, for example, a nitrogen atom, a carbon atom constituting an aromatic hydrocarbon ring, or the like.

As R₁₀₁, a hydrogen atom, a methyl group, an ethyl group, or a group represented by the following structure is preferable.

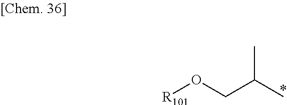

(In the structure, R₁₀₂ represents a hydrogen atom, a methyl group, or an ethyl group. * represents a bond.)

As the crosslinking agent, a melamine compound, a guanamine compound, a glycoluril compound, a urea compound, or a compound having a phenolic hydroxy group is preferable. These can be used alone or in combination of two or more thereof.

The melamine compound is not particularly limited as long as it is a melamine compound having a group that can react with a hydroxy group.

Examples of the melamine compound include hexamethylolmelamine, hexamethoxymethylmelamine, a compound in which 1 to 6 methylol groups of hexamethylolmelamine are methoxymethylated or a mixture thereof, hexamethoxyethylmelamine, hexaacyloxymethylmelamine, and a compound in which 1 to 6 methylol groups of hexamethylolmelamine are acyloxymethylated or a mixture thereof.

The guanamine compound is not particularly limited as long as it is a guanamine compound having a group that can react with a hydroxy group.

Examples of the guanamine compound include tetramethylolguanamine, tetramethoxymethylguanamine, a compound in which 1 to 4 methylol groups of tetramethylolguanamine are methoxymethylated or a mixture thereof, tetramethoxyethylguanamine, tetraacyloxyguanamine, and a compound in which 1 to 4 methylol groups of tetramethylolguanamine are acyloxymethylated or a mixture thereof.

The glycoluril compound is not particularly limited as long as it is a glycoluril compound having a group that can react with a hydroxy group.

Examples of the glycoluril compound include tetramethylolglycoluril, tetramethoxyglycoluril, tetramethoxymethylglycoluril, a compound in which 1 to 4 methylol groups of tetramethylolglycoluril are methoxymethylated or a mixture thereof, and a compound in which 1 to 4 methylol groups of tetramethylolglycoluril are acyloxymethylated or a mixture thereof.

The glycoluril compound may be, for example, a glycoluril derivative represented by the following Formula (1E).

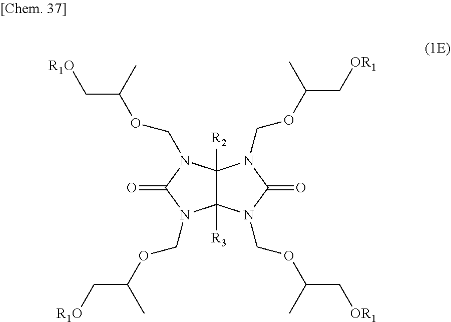

(In Formula (1E), four R₁'s each independently represent a methyl group or an ethyl group, and R₂ and R₃ each independently represent a hydrogen atom, an alkyl group having 1 to 4 carbon atoms, or a phenyl group.)

Examples of the glycoluril derivative represented by Formula (1E) include compounds represented by the following Formulas (1E-1) to (1E-6).

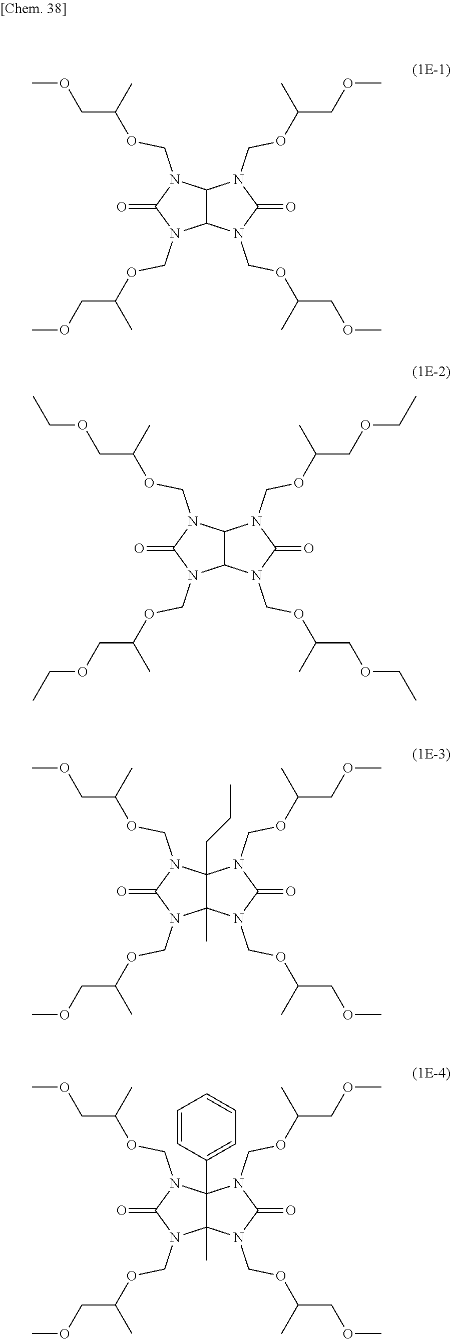

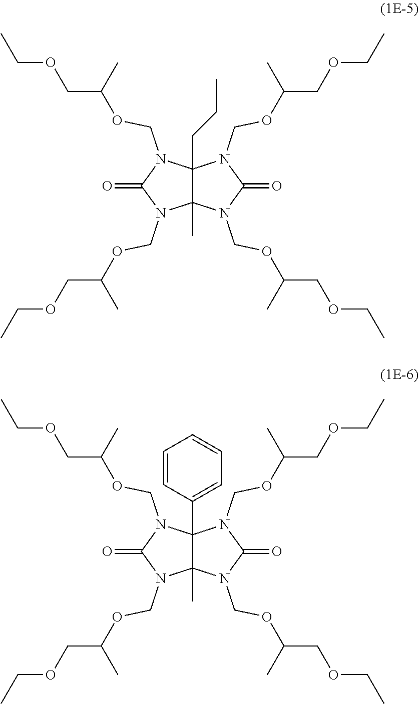

The glycoluril derivative represented by Formula (1E) is obtained, for example, by reacting a glycoluril derivative represented by the following Formula (2E) with at least one compound represented by the following Formula (3d).

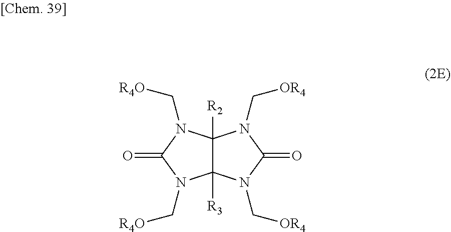

(In Formula (2E), R₂ and R₃ each independently represent a hydrogen atom, an alkyl group having 1 to 4 carbon atoms, or a phenyl group, and R^{a}'s each independently represent an alkyl group having 1 to 4 carbon atoms.)

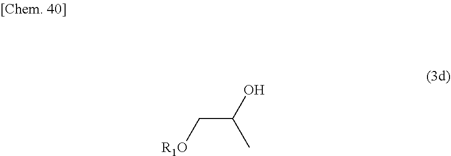

(In Formula (3d), R₁ represents a methyl group or an ethyl group.)

Examples of the glycoluril derivative represented by Formula (2E) include compounds represented by the following Formulas (2E-1) to (2E-4). Furthermore, examples of the compound represented by Formula (3d) include compounds represented by the following Formulas (3d-1) and (3d-2).

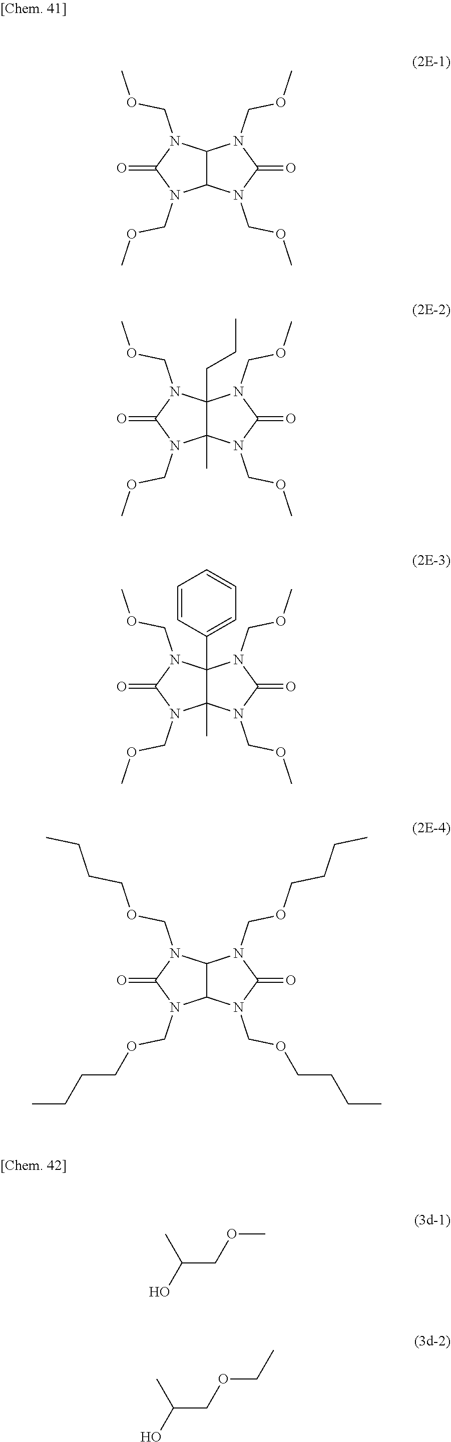

The urea compound is not particularly limited as long as it is a urea compound having a group that can react with a hydroxy group.

Examples of the urea compound include tetramethylolurea, tetramethoxymethylurea, a compound in which 1 to 4 methylol groups of tetramethylolurea are methoxymethylated or a mixture thereof, and tetramethoxyethylurea.

Examples of the compound having a phenolic hydroxy group include a compound represented by the following Formula (111) or (112).

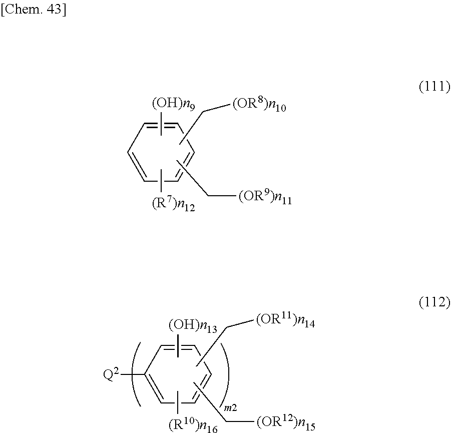

(In Formulas (111) and (112), 02 represents a single bond or an m2-valent organic group.

R⁸, R⁹, R¹¹, and R¹² each represent a hydrogen atom or a methyl group.

R⁷ and R¹⁰ each represent an alkyl group having 1 to 10 carbon atoms or an aryl group having 6 to 40 carbon atoms.
n₉ represents an integer of 1≤n₉≤3, n₁₀ represents an integer of 2≤n₁₀≤5, n₁₁ represents an integer of 0≤n₁₁≤3, n₁₂ represents an integer of 0≤n₁₂≤3, and 3≤(n₉+n₁₀+n₁₁+n₁₂)≤ 6.
n₁₃ represents an integer of 1≤n₁₃<3, n₁₄ represents an integer of 1≤n₁₄≤4, n₁₅ represents an integer of 0≤n₁₅≤3, n₁₆ represents an integer of 0≤n₁₆≤3, and 2≤(n₁₃+n₁₄+n₁₅+n₁₆)≤5.
m2 represents an integer of 2 to 10.)

Examples of the m2-valent organic group in 02 include an m2-valent organic group having 1 to 4 carbon atoms.

Examples of the compound represented by Formula (111) or (112) include the following compounds.

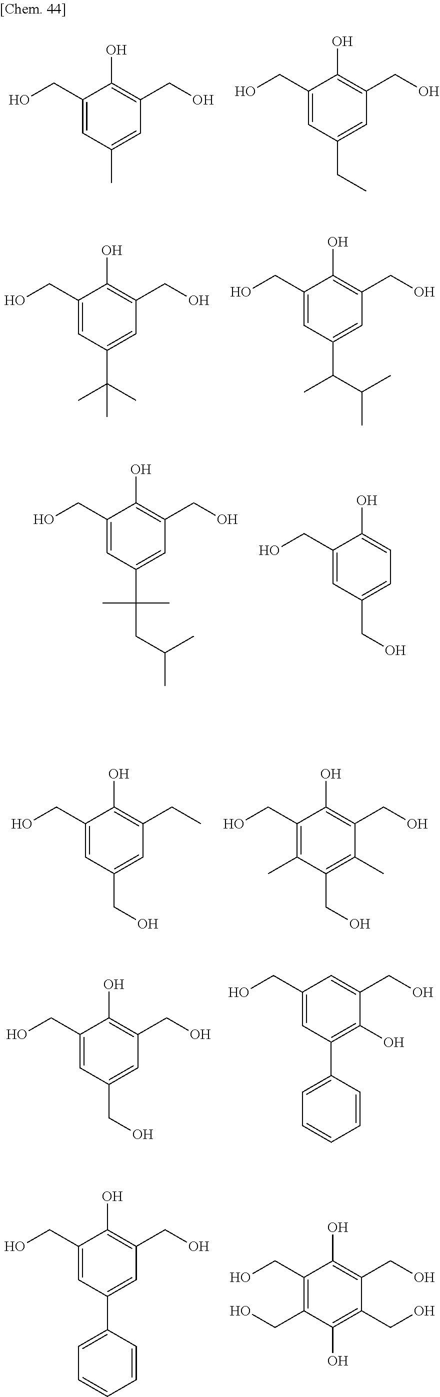

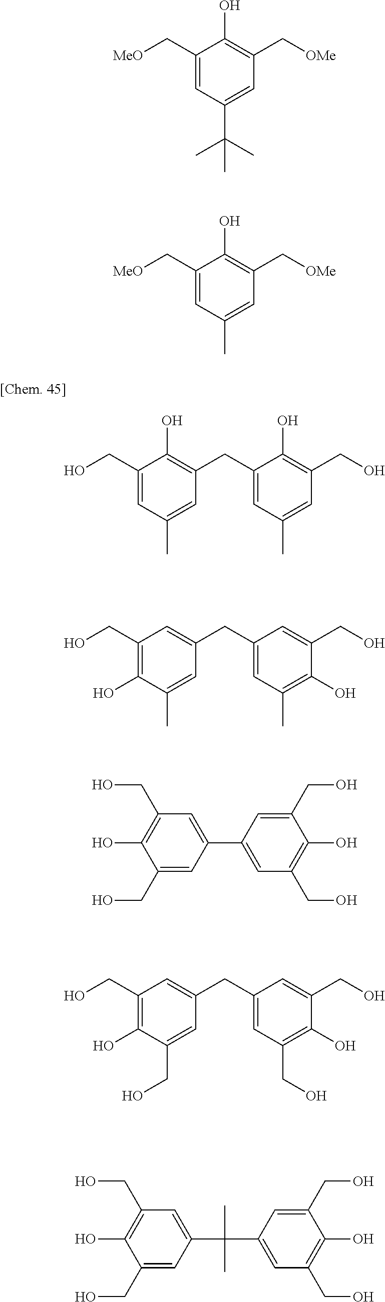

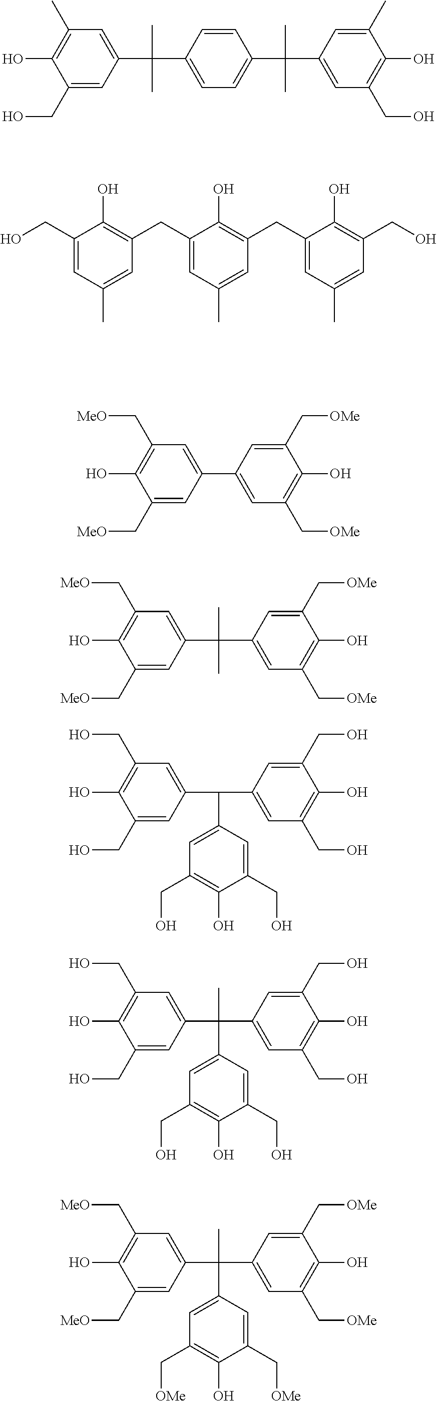

A product of Asahi Yukizai Corporation or Honshu Chemical Industry Co., Ltd. is available as the above compound. Examples of the product include TMOM-BP (trade name) manufactured by Asahi Yukizai Corporation.

Among them, the glycoluril compound is preferable. Specifically, tetramethylolglycoluril, tetramethoxyglycoluril, tetramethoxymethylglycoluril, a compound in which 1 to 4 methylol groups of tetramethylolglycoluril are methoxymethylated or a mixture thereof, and a compound in which 1 to 4 methylol groups of tetramethylolglycoluril are acyloxymethylated or a mixture thereof are preferable, and tetramethoxymethylglycoluril is preferable.

The molecular weight of the crosslinking agent (C) is not particularly limited, and is preferably 500 or less.

The content of the crosslinking agent (C) in the resist underlayer film-forming composition is not particularly limited, and is, for example, 1 mass % to 50 mass %, and preferably 5 mass % to 40 mass % relative to the polymer (A).

### <Solvent (D)>

As the solvent (D), an organic solvent that is generally used for a chemical solution for a semiconductor lithography step is preferable. Specific examples thereof include ethylene glycol monomethyl ether, ethylene glycol monoethyl ether, methyl cellosolve acetate, ethyl cellosolve acetate, diethylene glycol monomethyl ether, diethylene glycol monoethyl ether, propylene glycol, propylene glycol monomethyl ether, propylene glycol monoethyl ether, propylene glycol monomethyl ether acetate, propylene glycol propyl ether acetate, toluene, xylene, methyl ethyl ketone, methyl isobutyl ketone, cyclopentanone, cyclohexanone, cycloheptanone, 4-methyl-2 pentanol, methyl 2-hydroxyisobutyrate, ethyl 2-hydroxyisobutyrate, ethyl ethoxyacetate, 2-hydroxyethyl acetate, methyl 3-methoxypropionate, ethyl 3-methoxypropionate, ethyl 3-ethoxypropionate, methyl 3-ethoxypropionate, methyl pyruvate, ethyl pyruvate, ethyl acetate, butyl acetate, ethyl lactate, butyl lactate, 2-heptanone, methoxycyclopentane, anisole, y-butyrolactone, N-methylpyrrolidone, N, N-dimethylformamide, and N, N-dimethylacetamide. These solvents can be used alone or in combination of two or more thereof.

Among these solvents, propylene glycol monomethyl ether, propylene glycol monomethyl ether acetate, ethyl lactate, butyl lactate, and cyclohexanone are preferable. In particular, propylene glycol monomethyl ether and propylene glycol monomethyl ether acetate are preferable.

### <Catalyst (E)>

As the catalyst (E) contained as an optional component in the resist underlayer film-forming composition, a thermal acid generator is preferably used.

The catalyst (E) is a catalyst for reaction of the crosslinking agent (C) with a hydroxy group.

Examples of the thermal acid generator include sulfonic acid compounds and carboxylic acid compounds such as p-toluenesulfonic acid, trifluoromethanesulfonic acid, pyridinium-p-toluenesulfonate (pyridinium-p-toluenesulfonic acid), pyridinium phenolsulfonic acid, pyridinium-p-hydroxybenzenesulfonic acid (p-phenolsulfonic acid pyridinium salt), pyridinium-trifluoromethanesulfonic acid, salicylic acid, camphorsulfonic acid, 5-sulfosalicylic acid, 4-chlorobenzenesulfonic acid, 4-hydroxybenzenesulfonic acid, benzenedisulfonic acid, 1-naphthalenesulfonic acid, citric acid, benzoic acid, and hydroxybenzoic acid.

Only one catalyst can be used, or two or more catalysts can be used in combination.

When the catalyst is used, the content ratio of the catalyst is, for example, 0.1 mass % to 50 mass %, and preferably 1 mass % to 30 mass % relative to the crosslinking agent (C).

### <Other Components>

To the resist underlayer film-forming composition, a surfactant can be further added in order to further improve the application property for surface unevenness without the occurrence of pinholes, striations, and the like.

Examples of the surfactant include nonionic surfactants such as polyoxyethylene alkyl ethers such as polyoxyethylene lauryl ether, polyoxyethylene stearyl ether, polyoxyethylene cetyl ether, and polyoxyethylene oleyl ether, polyoxyethylene alkyl allyl ethers such as polyoxyethylene octylphenol ether and polyoxyethylene nonylphenol ether, polyoxyethylene/polyoxypropylene block copolymers, sorbitan fatty acid esters such as sorbitan monolaurate, sorbitan monopalmitate, sorbitan monostearate, sorbitan monooleate, sorbitan trioleate, and sorbitan tristearate, and polyoxyethylene sorbitan fatty acid esters such as polyoxyethylene sorbitan monolaurate, polyoxyethylene sorbitan monopalmitate, polyoxyethylene sorbitan monostearate, polyoxyethylene sorbitan trioleate, and polyoxyethylene sorbitan tristearate, fluorine surfactants EFTOP EF301, EF303, and EF352 (manufactured by Tohkem Products Corporation, trade name), MEGAFACE F171, F173, and R-30 (manufactured by DIC Corporation, trade name), FLUORAD FC430 and FC431 (manufactured by Sumitomo 3M Ltd., trade name), ASAHIGUARD AG710, SURFLON S-382, SC101, SC102, SC103, SC104, SC105, and SC106 (manufactured by Asahi Glass Co., Ltd., trade name), and organosiloxane polymer KP341 (manufactured by Shin-Etsu Chemical Co., Ltd.).

The blending amount of these surfactants is not particularly limited, and is usually 2.0 mass % or less, and preferably 1.0 mass % or less relative to the total solid content of the resist underlayer film-forming composition.

These surfactants may be added alone or in combination of two or more thereof.

The film constituent components contained in the resist underlayer film-forming composition, that is, the components excluding the solvent are, for example, 0.01 mass % to 10 mass % of the resist underlayer film-forming composition.

### (Resist Underlayer Film)

A resist underlayer of the present invention is a cured product of the above-described resist underlayer film-forming composition.

The resist underlayer film can be produced by, for example, applying the above-described resist underlayer film-forming composition onto a semiconductor substrate and baking the composition.

Examples of the semiconductor substrate to which the resist underlayer film-forming composition is applied include silicon wafer, germanium wafer, and compound semiconductor wafer such as gallium arsenide, indium phosphide, gallium nitride, indium nitride, and aluminum nitride.

In a case where a semiconductor substrate having an inorganic film formed on a surface thereof is used, the inorganic film is formed by, for example, an atomic layer deposition (ALD) method, a chemical vapor deposition (CVD) method, a reactive sputtering method, an ion plating method, a vacuum deposition method, or a spin coating method (spin-on-glass: SOG). Examples of the inorganic film include polysilicon film, silicon oxide film, silicon nitride film, boro-phospho silicate glass (BPSG) film, titanium nitride film, titanium nitride oxide film, tungsten film, gallium nitride film, and gallium arsenide film.

The resist underlayer film-forming composition of the present invention is applied onto such a semiconductor substrate by an appropriate application method such as a spinner or a coater. Thereafter, baking is performed using heating means such as a hot plate to form a resist underlayer film. The baking conditions are appropriately selected from a baking temperature of 100° C. to 400° C. and a baking time of 0.3 minutes to 60 minutes. The baking temperature is preferably 120° C. to 350° C., and more preferably 150° C. to 300° C., and the baking time is 0.5 minutes to 30 minutes, and more preferably 0.8 minutes to 10 minutes.

The film thickness of the resist underlayer film is, for example, 0.001 μm (1 nm) to 10 μm, 0.002 μm (2 nm) to 1 μm, 0.005 μm (5 nm) to 0.5 μm (500 nm), 0.001 μm (1 nm) to 0.05 μm (50 nm), 0.002 μm (2 nm) to 0.05 μm (50 nm), 0.003 μm (3 nm) to 0.05 μm (50 nm), 0.004 μm (4 nm) to 0.05 μm (50 nm), 0.005 μm (5 nm) to 0.05 μm (50 nm), 0.003 μm (3 nm) to 0.03 μm (30 nm), 0.003 μm (3 nm) to 0.02 μm (20 nm), 0.005 μm (5 nm) to 0.02 μm (20 nm), 0.005 μm (5 nm) to 0.02 μm (20 nm), 0.003 μm (3 nm) to 0.01 μm (10 nm), 0.005 μm (5 nm) to 0.01 μm (10 nm), 0.003 μm (3 nm) to 0.006 μm (6 nm), or 0.005 μm (5 nm).

In the present specification, the method of measuring the film thickness of the resist underlayer film is as follows.
Measurement device name: Ellipsometric film thickness measurement device RE-3100 (SCREEN Holdings Co., Ltd.)
Single wavelength ellipsometer (SWE) mode
Arithmetic average of 8 points (for example, 8-point measurement at intervals of 1 cm in a wafer-X direction)

### (Semiconductor Processing Substrate)

A semiconductor processing substrate of the present invention includes a semiconductor substrate and the resist underlayer film of the present invention.

Examples of the semiconductor substrate include the above-described semiconductor substrate.

The resist underlayer film is disposed on the semiconductor substrate, for example.

### (Semiconductor Element Producing Method and Pattern Forming Method)

A semiconductor element producing method of the present invention includes at least the following steps.
A step of forming a resist underlayer film on a semiconductor substrate using the resist underlayer film-forming composition of the present invention, and
A step of forming a resist film on the resist underlayer film

A pattern forming method of the present invention includes at least the following steps.
A step of forming a resist underlayer film on a semiconductor substrate using the resist underlayer film-forming composition of the present invention,
A step of forming a resist film on the resist underlayer film,
A step of irradiating the resist film with light or electron beams, and then developing the resist film to obtain a resist pattern, and
A step of etching the resist underlayer film using the resist pattern as a mask

Usually, a resist film is formed on the resist underlayer film.

The film thickness of the resist film is preferably 200 nm or less, more preferably 150 nm or less, still more preferably 100 nm or less, and particularly preferably 80 nm or less. In addition, the film thickness of the resist film is preferably 10 nm or more, more preferably 20 nm or more, and particularly preferably 30 nm or more.

The resist film formed on the resist underlayer film by a known method (for example, application and baking) is not particularly limited as long as it responds to light or electron beams (EB) used for irradiation. Both a negative photoresist and a positive photoresist can be used.

In the present specification, a resist responding to EB is also referred to as a photoresist.

Examples of the photoresist include a positive photoresist including a novolak resin and 1,2-naphthoquinone diazide sulfonic acid ester, a chemically amplified photoresist including a binder having a group that is decomposed by an acid to increase an alkali dissolution rate and a photoacid generator, a chemically amplified photoresist including a low-molecular compound that is decomposed by an acid to increase an alkali dissolution rate of the photoresist, an alkali-soluble binder, and a photoacid generator, a chemically amplified photoresist including a binder having a group that is decomposed by an acid to increase an alkali dissolution rate, a low-molecular compound that is decomposed by an acid to increase an alkali dissolution rate of the photoresist, and a photoacid generator, and a resist containing a metal element. Examples thereof include trade name V146G manufactured by JSR Corporation, trade name APEX-E manufactured by Shipley, trade name PAR710 manufactured by Sumitomo Chemical Co., Ltd., and trade names AR2772 and SEPR430 manufactured by Shin-Etsu Chemical Co., Ltd. In addition, examples thereof include fluorine-containing atomic polymer-based photoresist as described in Proc. SPIE, Vol. 3999, 330-334 (2000), Proc. SPIE, Vol. 3999, 357-364 (2000), and Proc. SPIE, Vol. 3999, 365-374 (2000).

In addition, the so-called resist compositions such as resist compositions, radiation-sensitive resin compositions, and high-resolution patterning compositions based on organometallic solutions, and the metal-containing resist compositions described in WO2019/188595, WO2019/187881, WO2019/187803, WO2019/167737, WO2019/167725, WO2019/187445, WO2019/167419, WO2019/123842, WO2019/054282, WO2019/058945, WO2019/058890, WO2019/039290, WO2019/044259, WO2019/044231, WO2019/026549, WO2018/193954, WO2019/172054, WO2019/021975, WO2018/230334, WO2018/194123, JP 2018-180525 A, WO2018/190088, JP 2018-070596 A, JP 2018-028090 A, JP 2016-153409 A, JP 2016-130240 A, JP 2016-108325 A, JP 2016-047920 A, JP 2016-035570 A, JP 2016-035567 A, JP 2016-035565 A, JP 2019-101417 A, JP 2019-117373 A, JP 2019-052294 A, JP 2019-008280 A, JP 2019-008279 A, JP 2019-003176 A, JP 2019-003175 A, JP 2018-197853 A, JP 2019-191298 A, JP 2019-061217 A, JP 2018-045152 A, JP 2018-022039 A, JP 2016-090441 A, JP 2015-10878 A, JP 2012-168279 A, JP 2012-022261 A, JP 2012-022258 A, JP 2011-043749 A, JP 2010-181857 A, JP 2010-128369 A, WO2018/031896, JP 2019-113855 A, WO2017/156388, WO2017/066319, JP 2018-41099 A, WO2016/065120, WO2015/026482, JP 2016-29498 A, JP 2011-253185 A, and the like can be used, although not limited thereto.

Examples of the resist composition include the following compositions.

An active ray-sensitive or radiation-sensitive resin composition containing: a resin A having a repeating unit having an acid-decomposable group in which a polar group is protected by a protecting group that is desorbed by the action of an acid; and a compound represented by the following General Formula (121).

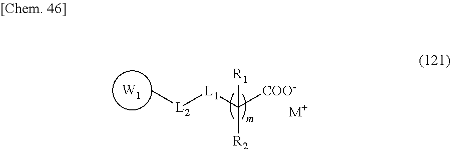

In General Formula (121), m represents an integer of 1 to 6.

R₁ and R₂ each independently represent a fluorine atom or a perfluoroalkyl group.

L₁ represents —O—, —S—, —COO—, —SO₂—, or —SO₃—.

L₂ represents an alkylene group which may have a substituent or a single bond.

W₁ represents a cyclic organic group which may have a substituent.

M⁺ represents a cation.

A metal-containing film-forming composition for extreme ultraviolet or electron lithography, containing a compound having a metal-oxygen covalent bond and a solvent, in which metal elements constituting the compound belong to periods 3 to 7 of groups 3 to 15 of the periodic table.

A radiation-sensitive resin composition containing a polymer having a first structural unit represented by the following Formula (31) and a second structural unit containing an acid-dissociable group represented by the following Formula (32), and an acid generator.

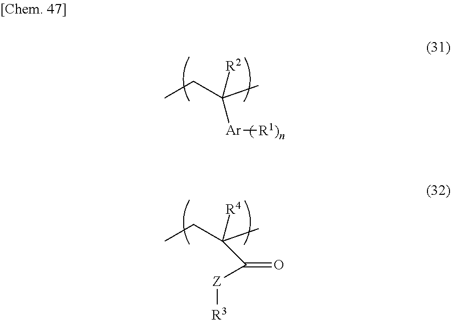

(In Formula (31), Ar is a group in which (n+1) hydrogen atoms are removed from an arene having 6 to 20 carbon atoms. R₁ is a hydroxy group, a sulfanyl group, or a monovalent organic group having 1 to 20 carbon atoms. n is an integer of 0 to 11. When n is 2 or more, a plurality of R₁'s are the same or different. R₂ is a hydrogen atom, a fluorine atom, a methyl group, or a trifluoromethyl group. In Formula (32), R₃ is a monovalent group having 1 to 20 carbon atoms and containing the acid-dissociable group. Z is a single bond, an oxygen atom, or a sulfur atom. R₄ is a hydrogen atom, a fluorine atom, a methyl group, or a trifluoromethyl group.)

A resist composition containing: a resin (A₁) including a structural unit having a cyclic carbonate ester structure, a structural unit represented by the following formula, and a structural unit having an acid unstable group; and an acid generator.

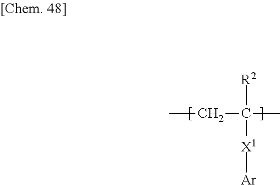

[In the formula,

R₂ represents an alkyl group having 1 to 6 carbon atoms which may have a halogen atom, a hydrogen atom, or a halogen atom, X¹ represents a single bond, —CO—O—*, or —CO—NR⁴—*, where * represents a bond with —Ar, R⁴ represents a hydrogen atom or an alkyl group having 1 to 4 carbon atoms, and Ar represents an aromatic hydrocarbon group having 6 to 20 carbon atoms which may have one or more groups selected from the group consisting of a hydroxy group and a carboxyl group.]

Examples of the resist film are as follows.

A resist film containing a base resin containing a repeating unit represented by the following Formula (a1) and/or a repeating unit represented by the following formula (a2), and a repeating unit that generates an acid bonded to a polymer main chain by exposure.

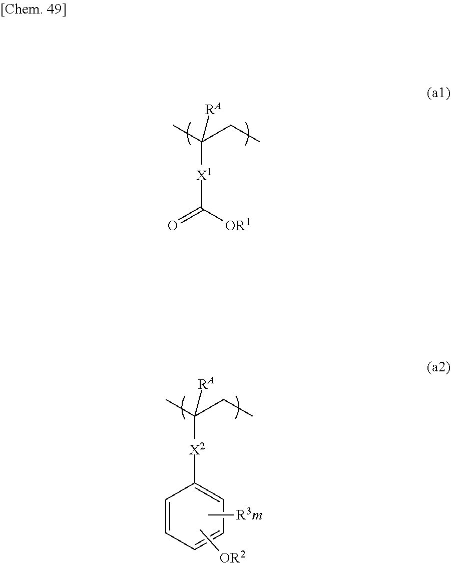

(In Formulas (a1) and (a2), R^{A}'s each independently are a hydrogen atom or a methyl group. R¹ and R² each independently are a tertiary alkyl group having 4 to 6 carbon atoms. R³'s each independently are a fluorine atom or a methyl group. m is an integer of 0 to 4. X¹ is a single bond, a phenylene group, a naphthylene group, or a linking group having 1 to 12 carbon atoms containing at least one selected from an ester bond, a lactone ring, a phenylene group, and a naphthylene group. X² is a single bond, an ester bond, or an amide bond.)

Examples of the resist material are as follows.

A resist material containing a polymer having a repeating unit represented by the following Formula (b1) or (b2).

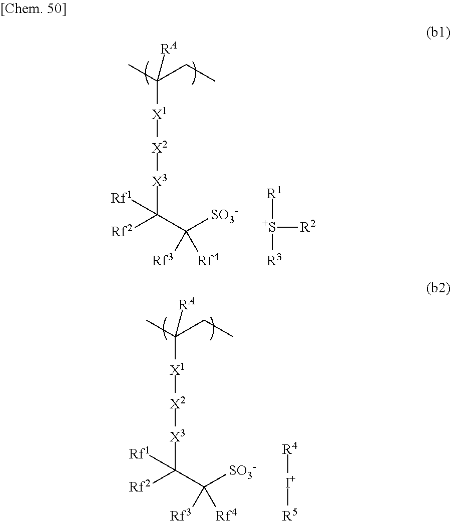

(In Formulas (b1) and (b2), R^{A} is a hydrogen atom or a methyl group. X¹ is a single bond or an ester group. X² is a linear, branched, or cyclic alkylene group having 1 to 12 carbon atoms or an arylene group having 6 to 10 carbon atoms, in which a part of a methylene group constituting the alkylene group may be substituted with an ether group, an ester group, or a lactone ring-containing group, and at least one hydrogen atom contained in X² is substituted with a bromine atom. X³ is a single bond, an ether group, an ester group, or a linear, branched, or cyclic alkylene group having 1 to 12 carbon atoms, in which a part of a methylene group constituting the alkylene group may be substituted with an ether group or an ester group. Rf¹ to Rf⁴ each independently are a hydrogen atom, a fluorine atom, or a trifluoromethyl group; however, at least one of them is a fluorine atom or a trifluoromethyl group. In addition, Rf¹ and Rf² may also be combined to form a carbonyl group. R¹ to R⁵ each independently are a linear, branched, or cyclic alkyl group having 1 to 12 carbon atoms, a linear, branched, or cyclic alkenyl group having 2 to 12 carbon atoms, an alkynyl group having 2 to 12 carbon atoms, an aryl group having 6 to 20 carbon atoms, an aralkyl group having 7 to 12 carbon atoms, or an aryloxyalkyl group having 7 to 12 carbon atoms, a part or all of the hydrogen atoms of these groups may be substituted with a hydroxy group, a carboxy group, a halogen atom, an oxo group, a cyano group, an amide group, a nitro group, a sultone group, a sulfone group, or a sulfonium salt-containing group, and a part of the methylene groups constituting these groups may be substituted with an ether group, an ester group, a carbonyl group, a carbonate group, or a sulfonic acid ester group. In addition, R¹ and R² may be bonded to form a ring together with the sulfur atom to which they are bonded.)

A resist material containing a base resin containing a polymer including a repeating unit represented by the following Formula (a).

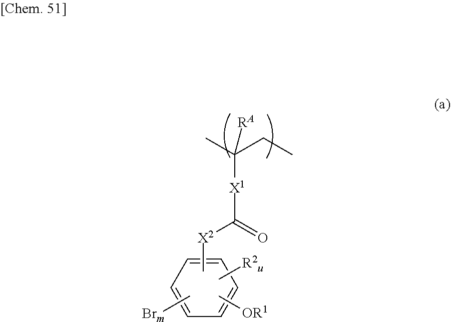

(In Formula (a), R^{A} is a hydrogen atom or a methyl group. R¹ is a hydrogen atom or an acid unstable group. R² is a linear, branched, or cyclic alkyl group having 1 to 6 carbon atoms or a halogen atom other than bromine. X¹ is a single bond, a phenylene group, or a linear, branched, or cyclic alkylene group having 1 to 12 carbon atoms which may contain an ester group or a lactone ring. X² is —O—, —O—CH₂—, or —NH—. m is an integer of 1 to 4. u is an integer of 0 to 3. Here, m+u is an integer of 1 to 4.)

A resist composition that generates an acid by exposure and whose solubility in a developer is changed by the action of an acid, containing a base material component (A) whose solubility in a developer is changed by the action of an acid, and a fluorine additive component (F) that exhibits decomposability in an alkaline developer, in which the fluorine additive component (F) contains a fluorine resin component (F1) having a structural unit (f1) containing a base-dissociable group and a structural unit (f2) containing a group represented by the following General Formula (f2-r-1).

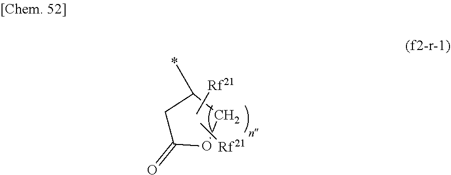

[In Formula (f2-r-1), Rf²¹'s each independently are a hydrogen atom, an alkyl group, an alkoxy group, a hydroxy group, a hydroxyalkyl group, or a cyano group. n″ is an integer of 0 to 2. * is a bond.]

The structural unit (f1) includes a structural unit represented by the following General Formula (f1-1) or a structural unit represented by the following General Formula (f1-2).

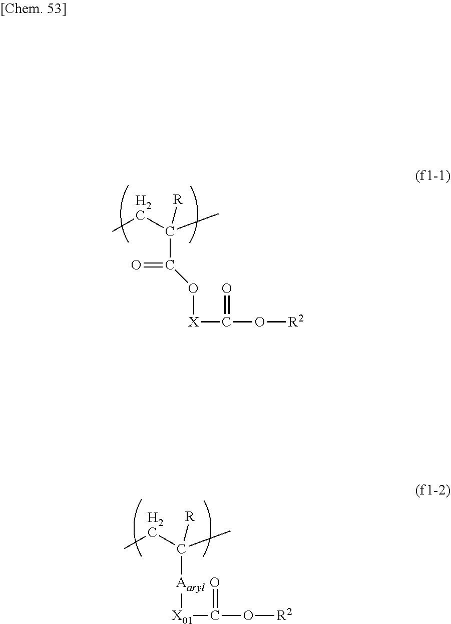

[In Formulas (f1-1) and (f1-2), R's each independently are a hydrogen atom, an alkyl group having 1 to 5 carbon atoms, or a halogenated alkyl group having 1 to 5 carbon atoms. X is a divalent linking group having no acid-dissociable moiety. A_{aryl} is a divalent aromatic cyclic group which may have a substituent. X₀₁ is a single bond or a divalent linking group. R₂'s each independently are an organic group having a fluorine atom.]

Examples of the coating, the coating solution, and the coating composition are as follows.

A coating including a metal oxo-hydroxo network having organic ligands via metal carbon and/or metal carboxylate bonds.

An inorganic oxo/hydroxo-based composition.

A coating solution containing: an organic solvent; a first organometallic composition represented by Formula R_{z}SnO_{(2-(z/2)-(x/2))} (OH)ₓ (where 0<z≤2 and 0< (z+x)≤4), Formula R′ₙSnX₄₋ₙ (where n=1 or 2) or a mixture thereof, where R and R′ are independently a hydrocarbyl group having 1 to 31 carbon atoms, and X is a ligand having a hydrolysable bond to Sn or a combination thereof; and a hydrolysable metal compound represented by Formula MX′ v (where M is a metal selected from groups 2 to 16 of the periodic table of the elements, v=2 to 6, and X′ is a ligand having a hydrolysable M-X bond or a combination thereof).

A coating solution containing an organic solvent and a first organometallic compound represented by Formula RSnO_{(3/2-x/2)} (OH)ₓ (where 0<x<3), in which the solution contains about 0.0025 M to 1.5 M of tin, R is an alkyl group or a cycloalkyl group having 3 to 31 carbon atoms, and the alkyl group or the cycloalkyl group is bonded to tin via a secondary or tertiary carbon atom.

An inorganic pattern forming precursor aqueous solution containing a mixture of water, a metal suboxide cation, a polyatomic inorganic anion, and a radiation-sensitive ligand containing a peroxide group.

Irradiation with light or electron beams is performed, for example, through a mask (reticle) for forming a predetermined pattern. For example, i-rays, a KrF excimer laser, an ArF excimer laser, extreme ultraviolet rays (EUV), or electron beams (EB) are used. The resist underlayer film-forming composition of the present invention is preferably applied for electron beam (EB) or extreme ultraviolet ray (EUV: 13.5 nm) irradiation, and more preferably applied for extreme ultraviolet ray (EUV) exposure.

The electron beam irradiation energy and the light exposure are not particularly limited.

Baking (PEB: post exposure bake) may be performed after light or electron beam irradiation and before development.

The baking temperature is not particularly limited, and is preferably 60° C. to 150° C., more preferably 70° C. to 120° C., and particularly preferably 75° C. to 110° C.

The baking time is not particularly limited, and is preferably 1 second to 10 minutes, more preferably 10 seconds to 5 minutes, and particularly preferably 30 seconds to 3 minutes.

For the development, for example, an alkaline developer is used.

The development temperature is, for example, 5° C. to 50° C.

The development time is, for example, 10 seconds to 300 seconds.

As the alkaline developer, it is possible to use, for example, aqueous solutions of alkalies, such as inorganic alkalies such as sodium hydroxide, potassium hydroxide, sodium carbonate, sodium silicate, sodium metasilicate, and aqueous ammonia, primary amines such as ethylamine and n-propylamine, secondary amines such as diethylamine and di-n-butylamine, tertiary amines such as triethylamine and methyldiethylamine, alcohol amines such as dimethylethanolamine and triethanolamine, quaternary ammonium salts such as tetramethylammonium hydroxide, tetraethylammonium hydroxide, and choline, and cyclic amines such as pyrrole and piperidine. It is also possible to use the above-described aqueous solutions of alkalies, to which alcohols such as isopropyl alcohol or surfactants such as nonionic surfactants are added in an appropriate amount. Of these, preferred developers are an aqueous solution of a quaternary ammonium salt, and more preferably an aqueous solution of tetramethylammonium hydroxide and an aqueous solution of choline. Furthermore, a surfactant or the like can be added to these developers. A method in which development is conducted using an organic solvent such as butyl acetate, instead of an alkaline developer, to develop a part where the alkali dissolution rate of the photoresist is not improved can also be used.

Next, the resist underlayer film is etched using the formed resist pattern as a mask. The etching may be dry etching or wet etching, and is preferably dry etching.

In a case where the inorganic film is formed on the surface of the semiconductor substrate used, the surface of the inorganic film is exposed; and in a case where the inorganic film is not formed on the surface of the semiconductor substrate used, the surface of the semiconductor substrate is exposed. Then, by subjecting the semiconductor substrate to a semiconductor substrate processing step using a known method (dry etching method, or the like), a semiconductor device can be produced.

### EXAMPLES

Next, the content of the present invention will be specifically described with reference to synthesis examples and examples, but the present invention is not limited thereto.

The weight average molecular weights of polymers shown in the following Synthesis Examples 1 and 2 are results of measurement by gel permeation chromatography (hereinafter, abbreviated as GPC). For the measurement, a GPC device manufactured by Tosoh Corporation was used, and measurement conditions and the like are as follows.

Column temperature: 40° C.

Flow rate: 0.35 m1/min

Eluent: tetrahydrofuran (THF)

Standard sample: polystyrene (Tosoh Corporation)

### Synthesis Example 1

To 6.87 g of propylene glycol monomethyl ether in a reaction container, 3.00 g of a monoallyl diglycidyl isocyanuric acid (manufactured by Shikoku Chemicals Corporation), 1.91 g of a 3,3′-dithiodipropionic acid (manufactured by Sakai Chemical Industry Co., Ltd., trade name: DTDPA), 0.57 of an adamantane carboxylic acid (manufactured by Tokyo Chemical Industry Co., Ltd.), and 0.14 g of tetrabutylphosphonium bromide (manufactured by ACROSS) were added and dissolved. After the reaction container was subjected to nitrogen substitution, a reaction was conducted at 105° C. for 8 hours to obtain a polymer solution. The polymer solution does not become cloudy even when cooled to room temperature, and has good solubility in propylene glycol monomethyl ether. GPC analysis was performed, and the polymer in the obtained solution had a weight average molecular weight of 5,000 as determined by standard polystyrene conversion. The polymer obtained in the present synthetic example has structural units represented by the following Formulas (1a), (2a), and (3a).

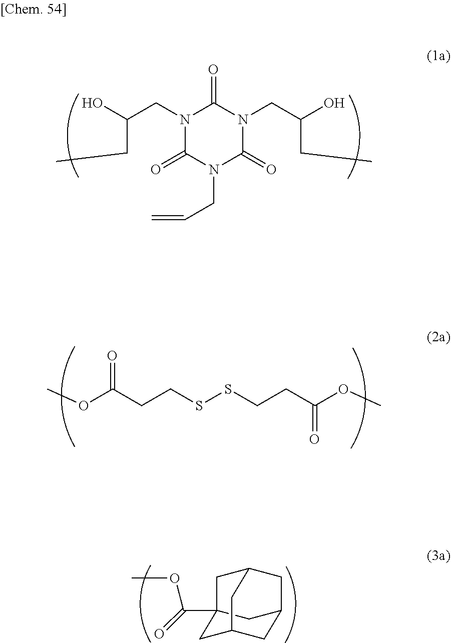

### Synthesis Example 2

To 56.00 g of propylene glycol monomethyl ether in a reaction container, 8.00 g of a monoallyl diglycidyl isocyanuric acid (manufactured by Shikoku Chemicals Corporation), 5.45 of barbital (manufactured by Hachidai Pharmaceutical Co., Ltd.), and 0.48 g of tetrabutylphosphonium bromide were added and dissolved. After the reaction container was subjected to nitrogen substitution, a reaction was conducted at reflux for 10 hours to obtain a polymer solution. The polymer solution does not become cloudy even when cooled to room temperature, and has good solubility in propylene glycol monomethyl ether. GPC analysis was performed, and the polymer in the obtained solution had a weight average molecular weight of 10,000 as determined by standard polystyrene conversion. The polymer obtained in the present synthetic example has structural units represented by the following Formulas (1a) and (1b).

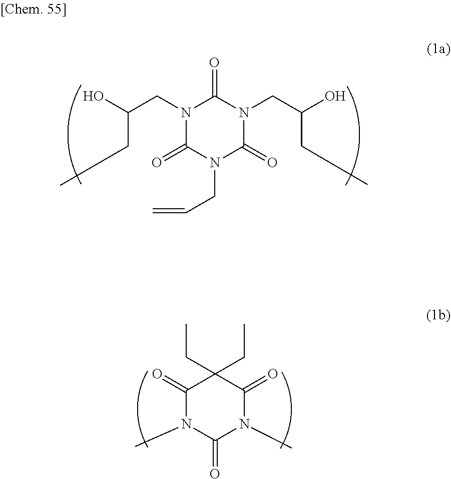

### Example 1

To 0.038 g of the polymer obtained in Synthesis Example 1 described above, 0.01 g of tetramethoxymethyl glycoluril (manufactured by Nihon Cytec Industries Inc.), 0.002 g of a pyridinium phenolsulfonic acid, 0.004 g of 4-hydroxy-1-naphthyl dimethylsulfonium trifluoromethanesulfonate (trade name: NDS-105, manufactured by Midori Kagaku Co., Ltd.) (PAG 1 described below), 25.9 g of propylene glycol monomethyl ether, and 2.99 g of propylene glycol monomethyl ether acetate were added and dissolved. Thereafter, the resulting solution was filtered using a polyethylene microfilter having a pore size of 0.05 μm to prepare a resist underlayer film-forming composition for lithography.

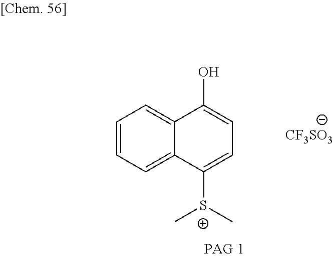

### Example 2

To 0.038 g of the polymer obtained in Synthesis Example 1 described above, 0.01 g of tetramethoxymethyl glycoluril (manufactured by Nihon Cytec Industries Inc.), 0.002 g of a pyridinium phenolsulfonic acid, 0.007 g of 4-hydroxy-1-naphthyl dimethylsulfonium trifluoromethanesulfonate (trade name: NDS-105, manufactured by Midori Kagaku Co., Ltd.) (PAG 1 described below), 25.9 g of propylene glycol monomethyl ether, and 2.99 g of propylene glycol monomethyl ether acetate were added and dissolved. Thereafter, the resulting solution was filtered using a polyethylene microfilter having a pore size of 0.05 μm to prepare a resist underlayer film-forming composition for lithography.

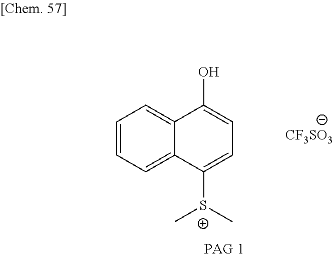

### Example 3

To 0.038 g of the polymer obtained in Synthesis Example 2 described above, 0.01 g of tetramethoxymethyl glycoluril (manufactured by Nihon Cytec Industries Inc.), 0.002 g of a pyridinium phenolsulfonic acid, 0.007 g of 4-hydroxyphenyldimethylsulfonium methyl sulfate (manufactured by Tokyo Chemical Industry Co., Ltd.) (PAG 2 described below), 25.9 g of propylene glycol monomethyl ether, and 2.99 g of propylene glycol monomethyl ether acetate were added and dissolved. Thereafter, the resulting solution was filtered using a polyethylene microfilter having a pore size of 0.05 μm to prepare a resist underlayer film-forming composition for lithography.

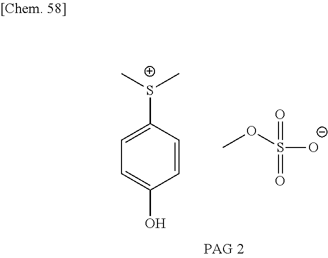

### Comparative Example 1

To 0.038 g of the polymer obtained in Synthesis Example 1 described above, 0.01 g of tetramethoxymethyl glycoluril (manufactured by Nihon Cytec Industries Inc.), 0.002 g of a pyridinium phenolsulfonic acid, 0.002 g of triphenylsulfonium trifluoromethanesulfonate (manufactured by Toyo Gosei Co., Ltd.) (PAG 3 described below), 25.9 g of propylene glycol monomethyl ether, and 2.99 g of propylene glycol monomethyl ether acetate were added and dissolved. Thereafter, the resulting solution was filtered using a polyethylene microfilter having a pore size of 0.05 μm to prepare a resist underlayer film-forming composition for lithography.

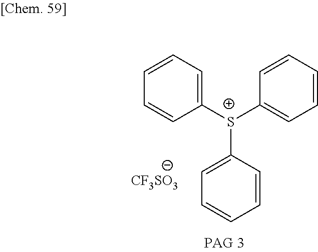 [SMILES: "CF3SO3" ; c1ccc([S+](c2ccccc2)c2ccccc2)cc1]

### Comparative Example 2

To 0.038 g of the polymer obtained in Synthesis Example 1 described above, 0.01 g of tetramethoxymethyl glycoluril (manufactured by Nihon Cytec Industries Inc.), 0.002 g of a pyridinium phenolsulfonic acid, 0.004 g of triphenylsulfonium trifluoromethanesulfonate (manufactured by Toyo Gosei Co., Ltd.) (PAG 3 described below), 25.9 g of propylene glycol monomethyl ether, and 2.99 g of propylene glycol monomethyl ether acetate were added and dissolved. Thereafter, the resulting solution was filtered using a polyethylene microfilter having a pore size of 0.05 μm to prepare a resist underlayer film-forming composition for lithography.

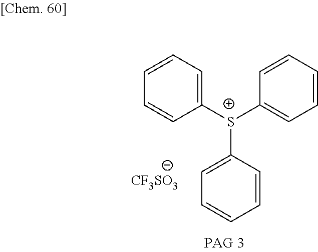 [SMILES: "CF3SO3" ; c1ccc([S+](c2ccccc2)c2ccccc2)cc1]

### Comparative Example 3

To 0.038 g of the polymer obtained in Synthesis Example 2 described above, 0.01 g of tetramethoxymethyl glycoluril (manufactured by Nihon Cytec Industries Inc.), 0.002 g of a pyridinium phenolsulfonic acid, 25.9 g of propylene glycol monomethyl ether, and 2.99 g of propylene glycol monomethyl ether acetate were added and dissolved. Thereafter, the resulting solution was filtered using a polyethylene microfilter having a pore size of 0.05 μm to prepare a resist underlayer film-forming composition for lithography.

The polymers and photoacid generators used in Examples 1 to 3 and Comparative Examples 1 to 3 are as listed in Table 1.

TABLE 1

| | | Photoacid Generator | |
|---|---|---|---|
| | Polymer | Kind | Amount Added |
| Example 1 | Synthesis Example 1 | PAG1 | 10 phr |
| Example 2 | Synthesis Example 1 | PAG1 | 20 phr |
| Example 3 | Synthesis Example 2 | PAG2 | 20 phr |
| Comparative | Synthesis Example 1 | PAG3 | 5 phr |
| Example 1 | | | |
| Comparative | Synthesis Example 1 | PAG3 | 10 phr |
| Example 2 | | | |
| Comparative | Synthesis Example 2 | None | |
| Example 3 | | | |

Amount Added in Table 1 indicates the amount (parts by mass) (phr; per hundred resin) of the photoacid generator added with respect to 100 parts by mass of the polymer.

### [Elution Test in Photoresist Solvent]

Each of the resist underlayer film-forming compositions of Examples 1, 2, and 3 and Comparative Examples 1, 2, and 3 was applied onto a silicon wafer as a semiconductor substrate by a spinner. The silicon wafer was disposed on a hot plate and baked at 205° C. for 1 minute to form a resist underlayer film (film thickness: 5 nm). These resist underlayer films were immersed at room temperature for 1 minute in a mixed solvent of propylene glycol monomethyl ether (70 vol %) and propylene glycol monomethyl ether acetate (30 vol %) used as a solvent of a photoresist-forming composition, and then heated at 100° C. for 30 seconds to remove the solvent. Then, the film thickness was measured. The results of the solvent resistance test are shown in Table 2. Cases where the reduction rate of the film thickness was 2% or less (1 Å or less) were evaluated as “good”, and cases where the reduction rate of the film thickness was more than 2% were evaluated as “poor”.

$$Film Reduction Rate ( \% ) = [ ( {A}_{0} - {A}_{1} ) / {A}_{0} ] \times 100$$

A₀: Film thickness before solvent resistance test

A₁: Film thickness after solvent resistance test

TABLE 2

| Examples | Solvent Resistance Test |
|---|---|
| Example 1 | Good |
| Example 2 | Good |
| Example 3 | Good |
| Comparative Example 1 | Good |
| Comparative Example 2 | Poor |
| Comparative Example 3 | Good |

In Examples 1 to 3 in which the photoacid generator was added in an amount equal to or more than the amount of PAG3 added in Comparative Example 2, the solvent resistance was good. Therefore, it was confirmed that the solvent resistance was improved by using PAG1 and PAG2, as compared to the case of using PAG3.

### [Formation of Positive Resist Pattern by Electron Beam Drawing Device]

Each of the resist underlayer film-forming compositions of Example 1 and Comparative Example 1 was applied onto a silicon wafer using a spinner. The silicon wafer was baked on a hot plate at 205° C. for 60 seconds to obtain a resist underlayer film having a film thickness of 5 nm. A positive resist solution for EUV (containing a methacrylic polymer) was spin-coated on the resist underlayer film, and heated at 130° C. for 60 seconds to form an EUV resist film. The resist film was exposed under predetermined conditions using an electron beam lithography device (ELS-G130). After exposure, the film was baked (PEB) at 100° C. for 60 seconds, cooled to room temperature on a cooling plate, and developed with an alkaline developer (2.38% TMAH), and then a line-and-space resist pattern with a CD of 30 nm/a pitch of 60 nm was formed. A scanning electron microscope (manufactured by Hitachi High-Tech Corporation, CG4100) was used to measure the length of the resist pattern. The results are shown in Table 3. Shown is the exposure amount necessary for obtaining a pattern with a CD size of 30 nm in the formation of the resist pattern. A lower number indicates that a target pattern can be obtained with a smaller exposure amount.

TABLE 3

| | Exposure Amount Necessary for |
|---|---|
| | Obtaining Pattern with CD Size of 30 |
| | nm |
| Example 1 | 450 uC |
| Comparative Example 1 | 496 uC |

It was found that, in Example 1, the exposure amount necessary for obtaining a pattern with a CD size of 30 nm can be reduced by about 11%, as compared to Comparative Example 1.

Each of the resist underlayer film-forming compositions of Example 3 and Comparative Example 3 was applied onto a silicon wafer using a spinner. The silicon wafer was baked on a hot plate at 205° C. for 60 seconds to obtain a resist underlayer film having a film thickness of 5 nm. A positive resist solution for EUV (containing a methacrylic polymer) was spin-coated on the resist underlayer film, and heated at 130° C. for 60 seconds to form an EUV resist film.

The resist film was exposed under predetermined conditions using an electron beam lithography device (ELS-G130). After exposure, the film was baked (PEB) at 100° C. for 60 seconds, cooled to room temperature on a cooling plate, and developed with an alkaline developer (2.38% TMAH), and then a line-and-space resist pattern with a CD of 22 nm/a pitch of 44 nm was formed. A scanning electron microscope (manufactured by Hitachi High-Tech Corporation, CG4100) was used to measure the length of the resist pattern. The results are shown in Table 4. Shown is the exposure amount necessary for obtaining a pattern with a CD size of 22 nm in the formation of the resist pattern. A lower number indicates that a target pattern can be obtained with a smaller exposure amount.

TABLE 4

| | Exposure Amount Necessary for Obtaining |
|---|---|
| | Pattern with CD Size of 22 nm |
| Example 3 | 553 uC |
| Comparative Example 3 | 570 uC |

It was found that, in Example 3, the exposure amount necessary for obtaining a pattern with a CD size of 22 nm can be reduced by about 3%, as compared to Comparative Example 3.

1. A resist underlayer film-forming composition for EB or EUV lithography, the resist underlayer film-forming composition comprising:
a hydroxy group-containing polymer (A);
a photoacid generator (B) containing a hydroxy group in a cationic part;
a crosslinking agent (C) that can react with a hydroxy group; and
a solvent (D).

2. The resist underlayer film-forming composition for EB or EUV lithography according to claim 1,
wherein the polymer (A) is at least one of
(i) a polyaddition product of a polyfunctional epoxy compound and one or more kinds selected from the group consisting of a polyfunctional carboxylic acid, a polyfunctional phenol, a polyfunctional thiol, isocyanuric acids, and barbituric acids,
(ii) a hydroxy group-containing poly(meth)acrylate, and
(iii) an addition-condensation product of an aromatic compound containing a phenolic hydroxy group, an aromatic amine, or an electron-rich aromatic compound, and an aldehyde compound or a carbonyl compound.

3. The resist underlayer film-forming composition for EB or EUV lithography according to claim 1,
wherein the photoacid generator (B) is a photoacid generator represented by the following Formula (1): 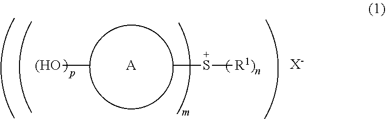
in Formula (1), p represents an integer of 1≤p≤4,
m represents an integer of 1≤m≤3, n represents an integer of 0≤n≤2, and n+m=3,
A represents a benzene ring which may be substituted or a naphthalene ring which may be substituted,
R₁ represents an alkyl group having 1 to 30 carbon atoms, a phenyl group which may be substituted, or a naphthyl group which may be substituted,
X⁻ represents a monovalent anion,
when m is 2 or more, A—(OH) p may be the same or different, and
when n is 2, R₁ may be the same or different.

4. The resist underlayer film-forming composition for EB or EUV lithography according to claim 1,
wherein the photoacid generator (B) is a photoacid generator represented by the following Formula (1-1): 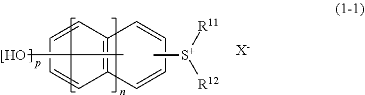
in Formula (1-1), R₁₁ represents an alkyl group having 1 to 6 carbon atoms, R₁₂ represents an alkyl group having 1 to 6 carbon atoms, n represents 0 or 1, p represents 1 or 2, and X″ represents a monovalent anion.

5. The resist underlayer film-forming composition for EB or EUV lithography according to claim 1,
wherein the crosslinking agent (C) is at least one of a melamine compound, a guanamine compound, a glycoluril compound, a urea compound, and a compound having a phenolic hydroxy group.

6. The resist underlayer film-forming composition for EB or EUV lithography according to claim 1, further comprising:
a catalyst (E) for reaction of the crosslinking agent (C) with a hydroxy group.

7. A resist underlayer film-forming composition comprising:
a hydroxy group-containing polymer (A);
a photoacid generator (B) containing a hydroxy group in a cationic part;
a crosslinking agent (C) that can react with a hydroxy group; and
a solvent (D),
wherein the photoacid generator (B) is a photoacid generator represented by the following Formula (1-1): 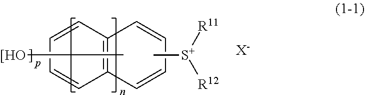
in Formula (1-1), R₁₁ represents an alkyl group having 1 to 6 carbon atoms, R₁₂ represents an alkyl group having 1 to 6 carbon atoms, n represents 0 or 1, p represents 1 or 2, and X⁻ represents a monovalent anion.

8. The resist underlayer film-forming composition according to claim 1, which is a resist underlayer film-forming composition for forming a resist underlayer film for a positive photoresist.

9. A resist underlayer film that is a cured product of the resist underlayer film-forming composition according to claim 1.

10. A semiconductor processing substrate comprising:
a semiconductor substrate; and
the resist underlayer film according to claim 9.

11. A semiconductor element producing method comprising the steps of:
forming a resist underlayer film on a semiconductor substrate using the resist underlayer film-forming composition according to claim 1; and
forming a resist film on the resist underlayer film.

12. A pattern forming method comprising the steps of:
forming a resist underlayer film on a semiconductor substrate using the resist underlayer film-forming composition according to claim 1;
forming a resist film on the resist underlayer film;
irradiating the resist film with light or electron beams, and then developing the resist film to obtain a resist pattern; and
etching the resist underlayer film using the resist pattern as a mask.

13. The resist underlayer film-forming composition according to claim 7, which is a resist underlayer film-forming composition for forming a resist underlayer film for a positive photoresist.

14. A resist underlayer film that is a cured product of the resist underlayer film-forming composition according to claim 7.

15. A semiconductor processing substrate comprising:
a semiconductor substrate; and
the resist underlayer film according to claim 14.

16. A semiconductor element producing method comprising the steps of:
forming a resist underlayer film on a semiconductor substrate using the resist underlayer film-forming composition according to claim 7; and
forming a resist film on the resist underlayer film.

17. A pattern forming method comprising the steps of:
forming a resist underlayer film on a semiconductor substrate using the resist underlayer film-forming composition according to claim 7;
forming a resist film on the resist underlayer film;
irradiating the resist film with light or electron beams, and then developing the resist film to obtain a resist pattern; and
etching the resist underlayer film using the resist pattern as a mask.
